(19) United States
(12) Patent Application Publication
(10) Pub. No.: US 2025/0341565 A1
(43) Pub. Date: Nov. 6, 2025

(54) APPARATUS FOR MEASURING A GATE LEAKAGE CURRENT OF A TRANSISTOR

(71) Applicant: CITY UNIVERSITY OF HONG KONG, Kowloon (HK)

(72) Inventors: Shu Hung Henry CHUNG, Hong Kong (HK); Ho Tin TANG, Tsuen Wan, Hong Kong (HK)

(73) Assignee: CITY UNIVERSITY OF HONG KONG, Kowloon (HK)

(21) Appl. No.: 18/656,143

(22) Filed: May 6, 2024

(51) Int. Cl. G01R 31/30; G01R 31/26; H03F 3/45

(52) U.S. Cl. CPC G01R 31/3008; G01R 31/2621; H03F 3/45174; H03F 2200/261

(57) ABSTRACT

An apparatus for measuring a gate leakage current of a MOSFET. The apparatus includes a current mirror adapted to be connected to a gate of a MOSFET, a gate driver adapted to generate a driving signal for the MOSFET, and a sensing resistor connected to the current mirror. An input current path of the current mirror is adapted to receive a gate leakage current of the MOSFET. The current mirror provides a high sensitivity of the measurement because the voltage across the current mirror is nearly constant, which therefore caters for different situations no matter if the gate leakage current is high or low.

### FIELD OF INVENTION

This invention relates to electronic circuits, and in particular to circuits for measuring a gate leakage current of a transistor.

### BACKGROUND OF INVENTION

Silicon carbide (SiC), which belongs to the wide bandgap family of materials, is a semiconductor compound containing silicon and carbon. It is utilized to produce switching devices, such as SiC MOSFETs, for high-power applications such as solar inverters, electric vehicles, and motor drives. Compared with traditional silicon (Si) MOSFETs, SiC MOSFETs enable higher switching speeds and breakdown voltages, achieving higher switching frequency and efficiency, and lower switching loss. However, gate oxide degradation is more severe in SiC MOSFETs than in Si MOSFETs because of the thinner gate oxide thickness, which causes a higher electric field across the gate oxide. Thus, gate oxide failure is well known to be one of the failure mechanisms in SiC MOSFETs.

Recently, it has been observed that gate-source leakage current is an effective precursor for real-time monitoring of gate-oxide conditions of SiC MOSFETs. The on-state gate-source leakage current can be increased significantly over time. A brand-new SiC device has the on-state gate-source leakage current on the order of hundreds of nano-Amperes (nA), but the value may increase to tens of (micro-Amperes) μA or (mini-Amperes) mA after aging, even if the device is still able to perform the switching function.

Various prior art techniques have been proposed to detect the leakage current or estimate the on-state gate-source resistance to perform real-time monitoring of gate oxide conditions. Since the gate current is proportional to the voltage across the gate resistor, the most straightforward method is based on measuring the voltage across Rₒₙ to indirectly determine the leakage current. However, because of various drawbacks in this method, the direct measurement of the gate leakage current by a sensing resistor is only suitable for measuring the gate leakage current of MOSFETs close to the end of life, because by then the gate leakage current would have reached an extreme value. Another conventional method proposes to employ capacitors to collect the charge derived from the leakage current. By observing the time taken for the capacitor voltage to reach a predetermined threshold, the magnitude of the leakage current can be indirectly determined. However, because capacitor voltage is easily influenced by a lot of factors, there is a need for calibration, and the estimation of leakage current needs consideration of duty cycle, which make the measurement inconvenient and error-prone.

### SUMMARY OF INVENTION

In the light of the foregoing background, it is an object of the present invention to focuses on the above-mentioned weakness and propose alternative method and apparatus of measuring gate leakage current of a transistor.

The above object is met by the combination of features of the main claim; the sub-claims disclose further advantageous embodiments of the invention.

One skilled in the art will derive from the following description other objects of the invention. Therefore, the foregoing statements of object are not exhaustive and serve merely to illustrate some of the many objects of the present invention.

Accordingly, the present invention in one aspect is an apparatus for measuring a gate leakage current of a MOSFET. The apparatus includes a current mirror adapted to be connected to a gate of a MOSFET, a gate driver adapted to generate a driving signal for the MOSFET, and a sensing resistor connected to the current mirror. An input current path of the current mirror is adapted to receive a gate leakage current of the MOSFET. The sensing resistor is located on an output current path of the current mirror.

In some embodiments, the apparatus further includes a turn-on resistor and a turn-off resistor, both of which are adapted to be connected to the gate of the MOSFET.

In some embodiments, the turn-on resistor is located on the input current path of the current mirror. The turn-off resistor has one end adapted to be connected to the MOSFET, and another end connected to the gate driver.

In some embodiments, the current mirror contains a first transistor and a second transistor having their base connected together. A collector of the first transistor is adapted to be connected to the gate of the MOSFET. A collector of the second transistor is connected to the sensing resistor.

In some embodiments, the collector of the first transistor is connected directly to the base of thereof. The apparatus further contains a diode that is connected between the collector and the base of the second transistor.

In some embodiments, an emitter of the first transistor and an emitter of the second transistor are connected directly to the gate driver.

In some embodiments, the apparatus further includes a bypass switch connected in parallel to the current mirror. The bypass switch is adapted to bypass the current mirror during a turn-on process of the MOSFET.

In some embodiments, the bypass switch contains a third transistor. The third transistor is located on a current path from the gate driver to MOSFET.

In some embodiments, an emitter of the third transistor is connected to the gate driver. A collector of the third transistor is adapted to connect to the MOSFET. A base of the third transistor is connected to the gate driver through a RC circuit.

In some embodiments, the apparatus further includes a discharging circuit connected to the current mirror. The discharging circuit is adapted to shorten a timer period required for the first transistor and the second transistor to transit from a saturation mode to a linear mode.

In some embodiments, the discharging circuit contains a comparator which has a first input connected to a reference voltage and a second input connected to the sensing resistor, a fourth transistor having a base connected an output of the comparator; a fourth resistor adapted to be connected between a collector of the fourth transistor and the gate of the MOSFET; and a third resistor connected between the base of the fourth transistor and a collector of the first transistor.

In some embodiments, the apparatus includes a diode connected between the base and the collector of the fourth transistor.

In some embodiments, one end of the sensing resistor is connected to the current mirror, and another end of the of the sensing resistor is connected to a source of the MOSFET.

Embodiments of the invention therefore provide apparatus and method for measuring gate leakage current of a MOSFET, which utilize a current mirror to perform switching operation and monitoring the gate source leakage current simultaneously. The current mirror provides a high sensitivity of the measurement because the voltage across the current mirror is nearly constant, which therefore caters for different situations no matter if the gate leakage current is high or low. In some embodiments of the invention, with a bypass switch the gate-source voltage of the MOSFET to be tested can be quickly increased, therefore shortening the time period required for the MOSFET to generate a steady-state leakage current for the test. As such, compared to some embodiments in which only the current mirror is present but without the bypass switch, the switching speed of the MOSFET to be tested is greatly improved when the bypass switch is configured in parallel with the current mirror in the circuit, which is comparable to the switching speed of MOFFET by conventional test circuits in which no current mirror is used. In some embodiments of the invention, with a discharging circuit the dynamic response of the current measurement circuit is also improved, which significantly shorten the time of measuring the gate-source leakage current. Moreover, the sensing operation of the current measurement circuit is independent of the duty cycle of the gate signal.

### BRIEF DESCRIPTION OF FIGURES

The foregoing and further features of the present invention will be apparent from the following description of preferred embodiments which are provided by way of example only in connection with the accompanying figures, of which:

FIG. 1 shows a comparison of measured gate-source leakage current I_{gss} of eight devices before and after undergoing 4000 cycles of short-circuit-current (SC) stress.

FIG. 2 shows an exemplary gate-driving circuit for a MOSFET.

FIG. 3a shows experimental results of the output of a MOSFET driver, vg, gate-source voltage, v_{gs}, and gate current, i_{g} for a brand new SiC MOSFET.

FIG. 3b is an enlarged view of steady-state waveforms as marked by the dash-lined block in FIG. 3a.

FIG. 3c shows experimental results of the output of a MOSFET driver, vg, gate-source voltage, v_{gs}, and gate current, i_{g}, after the SiC MOSFET of FIG. 3a has been aged for 4000 power cycles.

FIG. 3d is an enlarged view of steady-state waveforms as marked by the dash-lined block in FIG. 3c.

FIG. 4 shows a simplified circuit structure of an apparatus for measuring gate-leakage current according to one embodiment of the invention.

FIG. 5 shows a complete circuit structure an apparatus for measuring gate-leakage current according to another embodiment of the invention.

FIG. 6a shows the waveforms of v_{gs}, vₛ and i_{g} when R_{gss} equals to ∞, in a simulation of the circuit in FIG. 5.

FIG. 6b shows the waveforms of v_{gs}, vₛ and i_{g} when R_{gss} equals to 300 kΩ in the simulation.

FIG. 6c shows the waveforms of v_{gs}, vₛ and i_{g} when R_{gss} equals to 200 kΩ in the simulation.

FIG. 6d shows the waveforms of v_{gs}, vₛ and i_{g} when R_{gss} equals to 150 kΩ in the simulation.

FIG. 6e shows the waveforms of v_{gs}, vₛ and i_{g} when R_{gss} equals to 100 kΩ in the simulation.

FIG. 6f shows the waveforms of v_{gs}, vₛ and i_{g} when R_{gss} equals to 47 kΩ in the simulation.

FIG. 6g shows the waveforms of v_{gs}, vₛ and i_{g} when R_{gss} equals to 15 kΩ in the simulation.

FIG. 6h shows the waveforms of v_{gs}, vₛ and i_{g} when R_{gss} equals to 10 kΩ in the simulation.

FIG. 6i shows the waveforms of v_{gs}, vₛ and i_{g} when R_{gss} equals to 4.7 kΩ in the simulation.

FIG. 7 shows the schematic diagram of a test circuit for testing the performance of various circuits for measuring gate leakage current of a SiC MOSFET, according to an embodiment of the invention.

FIG. 8a shows one gate driving circuit used for comparison in the experimental setup.

FIG. 8b shows another gate driving circuit used for comparison in the experimental setup.

FIG. 9a shows measured waveforms of the drain-source voltage, v_{ds}, gate-source voltage, v_{gs}, output voltage of the gate driver, v_{g}, and drain current, i_{d}, upon turning on the SiC MOSFET for the circuit in FIG. 5 in the experiment.

FIG. 9b shows measured waveforms of the drain-source voltage, v_{ds}, gate-source voltage, v_{gs}, output voltage of the gate driver, v_{g}, and drain current, i_{d}, upon turning on the SiC MOSFET for the circuit in FIG. 8a in the experiment.

FIG. 9c shows measured waveforms of the drain-source voltage, v_{ds}, gate-source voltage, v_{gs}, output voltage of the gate driver, v_{g}, and drain current, i_{d}, upon turning on the SiC MOSFET for the circuit in FIG. 8b in the experiment.

FIG. 10a shows measured waveforms of the drain-source voltage, v_{ds}, gate-source voltage, v_{gs}, output voltage of the gate driver, v_{g}, and drain current, i_{d}, upon turning off the SiC MOSFET for the circuit in FIG. 5 in the experiment.

FIG. 10b shows measured waveforms of the drain-source voltage, v_{ds}, gate-source voltage, v_{gs}, output voltage of the gate driver, v_{g}, and drain current, i_{d}, upon turning off the SiC MOSFET for the circuit in FIG. 8a in the experiment.

FIG. 10c shows measured waveforms of the drain-source voltage, v_{ds}, gate-source voltage, v_{gs}, output voltage of the gate driver, v_{g}, and drain current, i_{d}, upon turning off the SiC MOSFET for the circuit in FIG. 8b in the experiment.

FIG. 11a shows the waveforms of v_{ds}, v_{gs}, vₛ and i_{d} under D=0.5, when R_{gss} equals to ∞, in a simulation of the circuit in FIG. 5.

FIG. 11b shows the waveforms of v_{ds}, v_{gs}, vₛ and i_{d} under D=0.5, when R_{gss} equals to 300 kΩ in the simulation.

FIG. 11c shows the waveforms of v_{ds}, v_{gs}, vₛ and i_{d} under D=0.5, when R_{gss} equals to 200 kΩ in the simulation.

FIG. 11d shows the waveforms of v_{ds}, v_{gs}, vₛ and i_{d} under D=0.5, when R_{gss} equals to 150 kΩ in the simulation.

FIG. 11e shows the waveforms of v_{ds}, v_{gs}, vₛ and i_{d} under D=0.5, when R_{gss} equals to 100 kΩ in the simulation.

FIG. 11f shows the waveforms of v_{ds}, v_{gs}, vₛ and i_{d} under D=0.5, when R_{gss} equals to 47 kΩ in the simulation.

FIG. 11g shows the waveforms of v_{ds}, v_{gs}, vₛ and i_{d} under D=0.5, when R_{gss} equals to 15 kΩ in the simulation.

FIG. 11h shows the waveforms of v_{ds}, v_{gs}, vₛ and i_{d} under D=0.5, when R_{gss} equals to 10 kΩ in the simulation.

FIG. 11i shows the waveforms of v_{ds}, v_{gs}, vₛ and i_{d} under D=0.5, when R_{gss} equals to 4.7 kΩ in the simulation.

FIG. 12a shows the waveforms of v_{ds}, v_{gs}, vₛ and i_{d} under D=0.2, when R_{gss} equals to ∞, in a simulation of the circuit in FIG. 5.

FIG. 12b shows the waveforms of v_{ds}, v_{gs}, vₛ and i_{d} under D=0.2, when R_{gss} equals to 300 kΩ in the simulation.

FIG. 12c shows the waveforms of v_{ds}, v_{gs}, vₛ and i_{d} under D=0.2, when R_{gss} equals to 200 kΩ in the simulation.

FIG. 12d shows the waveforms of v_{ds}, v_{gs}, vₛ and i_{d} under D=0.2, when R_{gss} equals to 150 kΩ in the simulation.

FIG. 12e shows the waveforms of v_{ds}, v_{gs}, vₛ and i_{d} under D=0.2, when R_{gss} equals to 100 kΩ in the simulation.

FIG. 12f shows the waveforms of v_{ds}, v_{gs}, vₛ and i_{d} under D=0.2, when R_{gss} equals to 47 kΩ in the simulation.

FIG. 12g shows the waveforms of v_{ds}, v_{gs}, vₛ and i_{d} under D=0.2, when R_{gss} equals to 15 kΩ in the simulation.

FIG. 12h shows the waveforms of v_{ds}, v_{gs}, vₛ and i_{d} under D=0.2, when R_{gss} equals to 10 kΩ in the simulation.

FIG. 12i shows the waveforms of v_{ds}, v_{gs}, vₛ and i_{d} under D=0.2, when R_{gss} equals to 4.7 kΩ in the simulation.

FIG. 13a shows the waveforms of v_{ds}, v_{gs}, vₛ and i_{d} under D=0.8, when R_{gss} equals to ∞, in a simulation of the circuit in FIG. 5.

FIG. 13b shows the waveforms of v_{ds}, v_{gs}, vₛ and i_{d} under D=0.8, when R_{gss} equals to 300 kΩ in the simulation.

FIG. 13c shows the waveforms of v_{ds}, v_{gs}, vₛ and i_{d} under D=0.8, when R_{gss} equals to 200 kΩ in the simulation.

FIG. 13d shows the waveforms of v_{ds}, v_{gs}, vₛ and i_{d} under D=0.8, when R_{gss} equals to 150 kΩ in the simulation.

FIG. 13e shows the waveforms of v_{ds}, v_{gs}, vₛ and i_{d} under D=0.8, when R_{gss} equals to 100 kΩ in the simulation.

FIG. 13f shows the waveforms of v_{ds}, v_{gs}, vₛ and i_{d} under D=0.8, when R_{gss} equals to 47 kΩ in the simulation.

FIG. 13g shows the waveforms of v_{ds}, v_{gs}, vₛ and i_{d} under D=0.8, when R_{gss} equals to 15 kΩ in the simulation.

FIG. 13h shows the waveforms of v_{ds}, v_{gs}, vₛ and i_{d} under D=0.8, when R_{gss} equals to 10 kΩ in the simulation.

FIG. 13i shows the waveforms of v_{ds}, v_{gs}, vₛ and i_{d} under D=0.8, when R_{gss} equals to 4.7 kΩ in the simulation.

FIG. 14 shows the relationship between vₛ and I_{gss} under the three duty cycle conditions.

In the drawings, like numerals indicate like parts throughout the several embodiments described herein.

### DETAILED DESCRIPTION OF THE PREFERRED EMBODIMENTS

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

As used herein and in the claims, “couple” or “connect” refers to electrical coupling or connection either directly or indirectly via one or more electrical means unless otherwise stated. When describing a “direct connection”, it means two circuit components, nodes, or terminals are connected to each other without any intermediate components therebetween.

Before describing apparatuses for gate leakage current detection according to exemplary embodiments of the invention, the intrinsic characteristics of SiC MOSFETs in terms of gate-source leakage current will be discussed. FIG. 1 shows a comparison of the measured gate-source leakage current I_{gss} of eight SiC MOSFET devices before and after undergoing 4000 cycles of short-circuit-current (SC) stress. The results reveal a notable increase in I_{gss}, with a significant percentage increment observed from a few picoamperes (pA) to tens or even hundreds of mA.

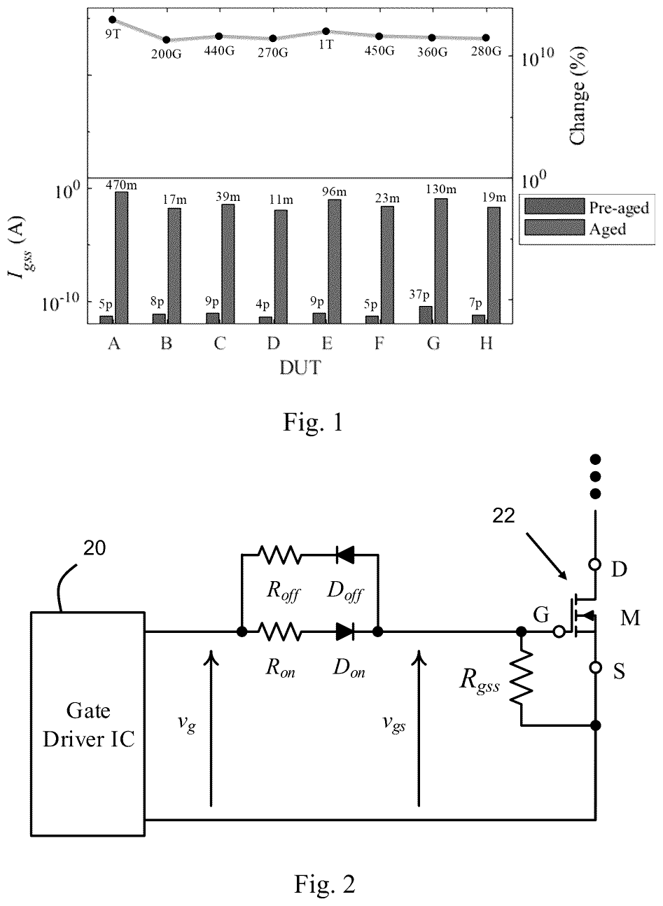

FIG. 2 shows an exemplary gate-driving circuit, in which a MOSFET driver in the form of a gate driver IC 20 drives a SiC MOSFET 22 via a polarized resistive network. The input gate of the MOSFET 22 is modelled by a capacitor C_{gs} to represent the gate-source capacitance and a resistor R_{gss} to represent the gate-source leakage resistance. The gate driver IC 20 delivers a logical “HIGH” signal to turn on the MOSFET 22 via the diode D_{ON} and the turn-on gate resistor R_{ON}. Conversely, the gate driver IC 20 delivers a logical “LOW” signal to turn off the MOSFET 22 via the diode D_{OFF} and the turn-off gate resistor R_{OFF}. R_{ON} and R_{OFF} are sometimes of different values to control the turn-on and turn-off speeds. The polarized resistive network can be of other structures, but the objective of controlling the turn-on and turn-off profiles is the same. To reduce switching losses, the values of R_{ON} and R_{OFF} typically range from several ohms to tens of ohms.

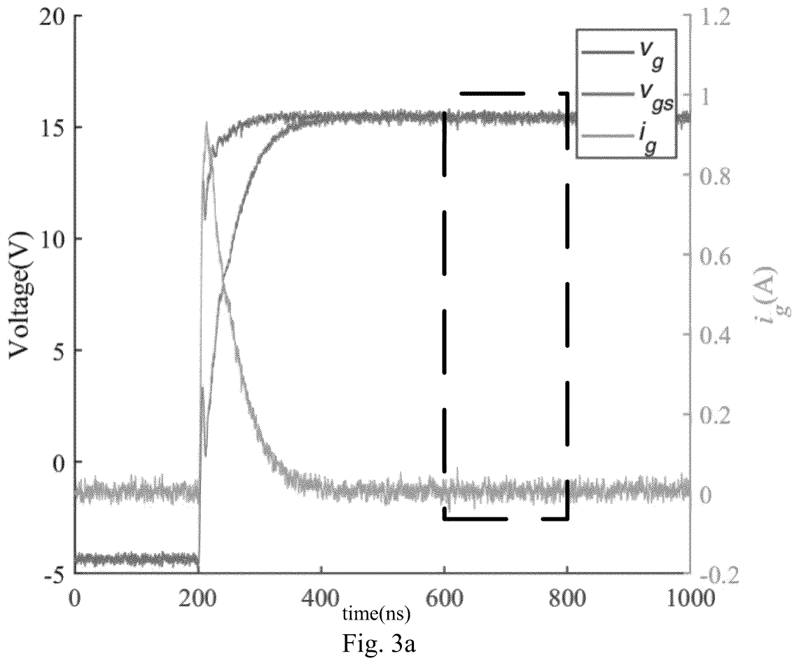

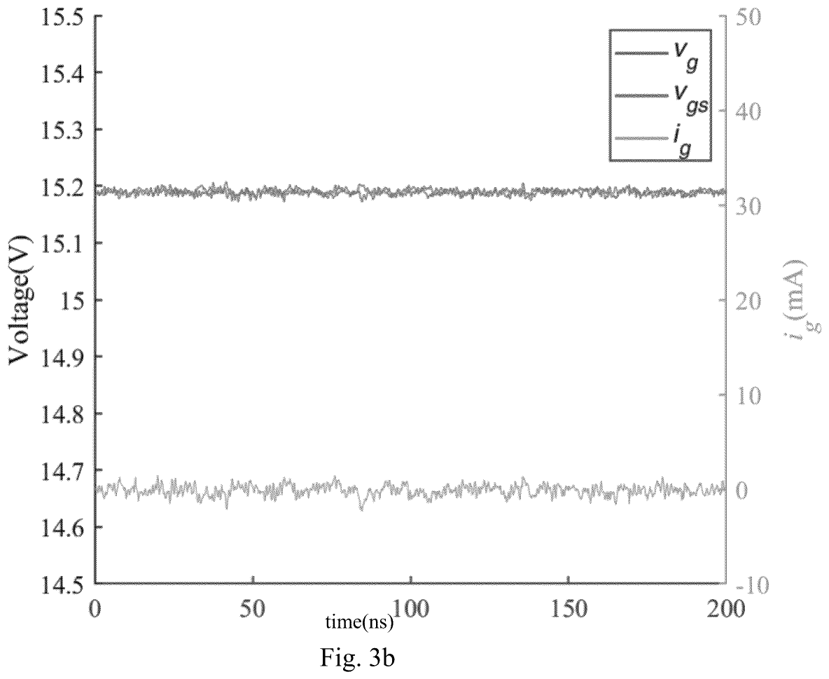

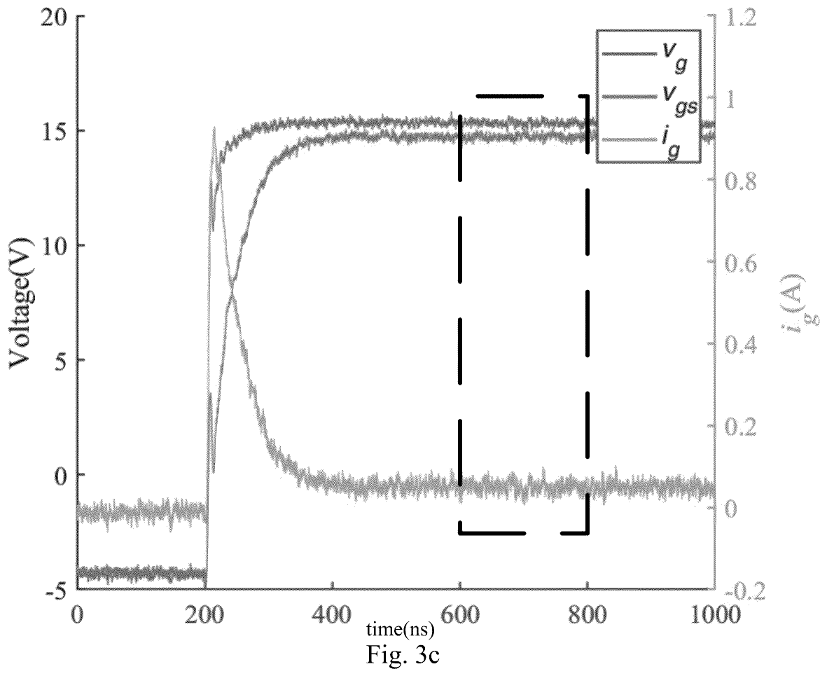

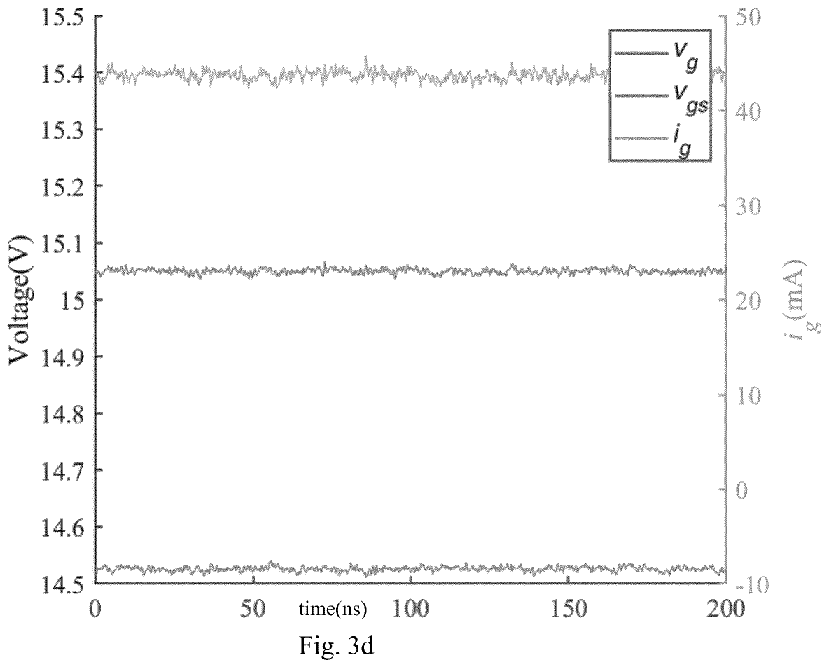

FIGS. 3a-3d show the experimental results of the output of a MOSFET driver, v_{g}, gate-source voltage, v_{gs}, and gate current, i_{g}. FIG. 3a shows the results for a brand new SiC MOSFET, and FIG. 3b shows the magnified steady-state waveforms. FIG. 3c and FIG. 3d show the corresponding results after aging the same SiC MOSFET for 4000 power cycles respectively. Upon turning on the SiC MOSFET, i_{g} contains a high input current pulse through C_{gs} because C_{gs} is initially uncharged. When C_{gs} has been fully charged, a relatively steady-state current will flow through R_{gss}, i.e., the on-state gate-source leakage current as shown in FIG. 3b and FIG. 3d. One can see that the gate leakage current of the SiC MOSFET has an increase from nearly zero to 43 mA after the above-mentioned power cycling. This increase results in a loading effect on the MOSFET driver output, leading to a reduction in v_{g} from 15.2V to 15.05V and v_{gs} from 15.2V to 14.52V.

Various prior art techniques have been proposed to detect the leakage current or estimate the on-state gate-source resistance to perform real-time monitoring of gate oxide conditions. Since the gate current is proportional to the voltage across the gate resistor, the most straightforward method is based on measuring the voltage across Rₒₙ to indirectly determine the leakage current. However, there are practical challenges in the voltage measurement circuit which include 1) the amplifier in the measurement circuit must have a wide common-mode voltage capability; 2) the amplifier should have wide bandwidth; 3) the input bias current of the amplifier should be at least one order of magnitude less than the target gate leakage current; and 4) input offset voltage of the amplifier should be at least one order of magnitude smaller than the minimum threshold voltage on the resistor. As a result, the direct measurement of voltage across Rₒₙ is only suitable for measuring the gate leakage current of MOSFETs when they are close to their end of life, because by then the gate leakage current would have reached an extreme value.

Instead of directly measuring the leakage current, an alternative method involves employing capacitors to collect the charge derived from the leakage current. By observing the time taken for the capacitor voltage to reach a predetermined threshold, the magnitude of the leakage current can be indirectly determined. However, it's important to note that the capacitor voltage is influenced not only by the leakage current but also by the durations of the rise time and fall time of the gate-source voltage. Thus, calibration is necessary to mitigate the impact of these voltage transitions on the calculation of the leakage current. Additionally, the rate of change of the capacitor voltage varies with the duty cycle, so it's essential to consider the duty cycle when estimating the leakage current. Building upon the above approach, an extension of the approach has been proposed in which the measurement of the average gate-source voltage is introduced, aiming to eliminate the influence of the duty cycle. By calculating the ratio between the measured average gate-source voltage and the charge accumulated on the capacitor, the gate leakage resistance can be determined. However, calibration is still required in this extended approach to address the impact of voltage transitions on the accuracy of the measurement.

Inventors of the present invention have therefore realized that although in some prior art methods, measurement of the gate leakage current can be achieved by using a series resistor which is the most straightforward way, such methods did not consider the fluctuation of the gate leakage current. For improved output sensitivity, it is therefore preferable to use a large series resistor when the gate leakage current is low. Conversely, when the gate leakage current is high, a small series resistor is more suitable. This approach ensures accurate and effective measurement of the gate leakage current. However, it is crucial to note that using a large series resistor can influence the waveshape of the gate-source voltage negatively.

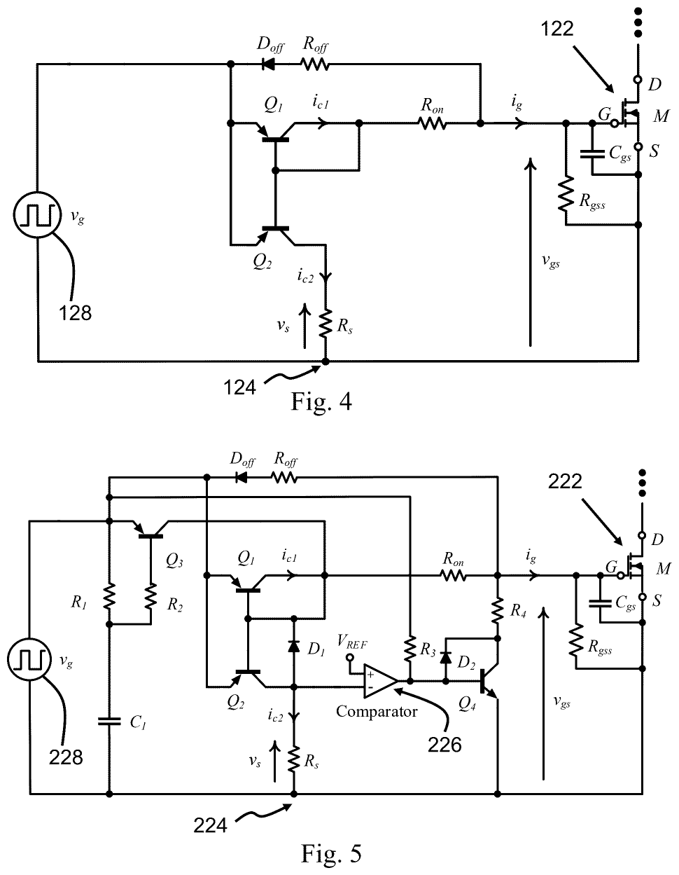

Instead of using a series resistor, one embodiment of the current invention which is an apparatus for measuring a gate leakage current of a MOSFET utilizing a current mirror, as depicted in FIG. 4, which is used to mirror the gate leakage current. FIG. 4 also shows a SiC MOSFET 122 that is to be tested by the apparatus. The current mirror in the current measurement circuit of FIG. 4 is formed by transistors Q₁ and Q₂ which in one example are both PNP transistors. Bases of Q₁ and Q₂ are connected together, and they are connected to the collector of Q₁. In other words, the collector and the base of Q₁ are shorted. The emitters of both Q₁ and Q₂ are connected to a voltage source 128 that functions as a gate driver and is able to generate a gate driving signal such as a square wave. The collector of Q₂ is connected to a sensing resistor Rs, which in turn has a reference node 124 connected both to the voltage source 128 and to a source of the MOSFET 122. The collector of Q₁ is connected to a first end of a turn-on resistor Rₒₙ, and a second end of Rₒₙ is connected to a gate of the MOSFET 122. For a turn-off resistor R_{off} in the circuit, it has a first end connected to the voltage source 128 through a diode D_{off}, and a second end connected to the gate of the MOSFET 122. The diode D_{off} has a positive terminal connected to the turn-off resistor R_{off} and a negative terminal connected to the voltage source 228.

The current mirror in FIG. 4 is adapted to mirror the current passing through an input current path of the current mirror, which is the path of the collector current i_{c1} of Q₁. Q₁ is thus in the input branch of the current mirror, while Q₂ is in the output branch of the current mirror. The gate current i_{g} flows through Q₁ and the collector current i_{c1} is almost the same as i_{g} as the base current of Q₁ is much smaller than i_{c1}. The collector current of Q₂ is the mirrored current of i_{c1} and is therefore also almost the same as the gate current i_{g}. The voltage across Rs can then reflect the gate current i_{g}. The gate resistors Rₒₙ and R_{off} serve the same functions as those described above with respect to FIG. 2.

The voltage across the current mirror is nearly constant. Therefore, when the magnitude of the gate leakage current is small, the equivalent resistance is large. Conversely, when the magnitude of the gate leakage current is large, the equivalent resistance is small. The sensitivity of the apparatus in FIG. 4 as compared to conventional measuring circuits is therefore high, based on the analysis provided previously. In addition, in FIG. 4 the reference node 124 of the sensing resistor is directly connected to the source of the MOSFET 122, which eliminates the need for a differential measurement to measure the voltage across the series resistor. As the mirrored current i_{c2} is connected to the sensing resistor Rs, an operating range of the current measurement is set, without affecting the gate-source voltage v_{gs}. This approach simplifies the measurement process, making it more efficient and straightforward.

Turning to FIG. 5, according to another embodiment of the invention there is provided an apparatus for measuring a gate leakage current of a SiC MOSFET 222. Similar to the circuit in FIG. 4, the core part of the current measurement circuit in FIG. 5 contains a current mirror that has a same configuration as that in FIG. 4, which will not be described herein again for the sake of brevity. Compared to the circuit of FIG. 4, the circuit in FIG. 5 additionally contains a bypass switch and a discharging circuit. As a steady-state leakage current could be observed only after the MOSFET 222 has been turned on completely, the bypass switch, which is implemented by transistor Q₃, is connected in parallel with the current mirror. In particular, an emitter of the Q₃, and those of the transistors Q₁ and Q₂, are connected to the voltage source 228 at the same time. Also, a collector of the transistor Q₃ is connected, and those of the transistors Q₁ and Q₂, are all connected to the gate of the MOSFET 222 through the turn-on resistor Rₒₙ. Upon turning on the MOSFET 222, the bypass transistor Q₃ will be turned on to drive the MOSFET 222, so that the gate-source voltage v_{gs} is increased in a short time. Afterwards, the current mirror is engaged to perform the steady-state gate leakage current measurement.

The bypass switch includes the transistor Q₃, and additionally a first resistor R₁, a second resistor R₂, and a capacitor C₁. The resistors R₁, R₂ and the capacitor C₁ form a RC circuit, which connects the base of the transistor Q₃ to the voltage source 228. A first end of R₁ is connected to the voltage source 228 and the emitter of the transistor Q₃. A first end of R₂ is connected to the base of the transistor Q₃. Second ends of R₁ and R₂ are connected to a first end of the capacitor C₁, while a second end of C₁ is connected to the reference node 224 of the sensing resistor Rs to which the source of the MOSFET 222 is also connected.

The discharging circuit includes a fourth transistor Q₄ in the circuit, a comparator 226, resistors R₃ and R₄, and diodes D₁ and D₂. The diode D₁ has a positive terminal connected to a collector of Q₂, and a negative terminal connected to the base and a collector of Q₁ (the two of which are connected together as mentioned above). The positive terminal of the diode D₁ also connects to an end of the sensing resistor Rs. The comparator 226 has a first input connected to a reference voltage VREF and a second input connected to the collector of Q₂ (and thus also to the sensing resistor Rs and the positive terminal of the diode D₁). The output of the comparator 226 is connected to a base of the transistor Q₄, and also to a first end of the resistor R₃ as well as a positive terminal of the diode D₂. A second end of the resistor R₃ is connected to the voltage source 228. A negative end of the diode D₂ is connected to a collector of Q₄, and to a first end of the resistor R₄. A second end of R₄ is connected to the gate of the MOSFET 222. Finally, an emitter of Q₄ is connected to the reference node 224.

Having described the circuit components in the apparatus of FIG. 5, now the working principle of the circuit will be described. When v_{g} is changed from logical “HIGH” to logical “LOW”, the voltage level of v_{g} will change from positive to zero or negative in order to turn off the MOSFET. However, at this moment v_{gs} is still at a high potential because of the gate-source capacitance C_{gs} that contains charges. Thus, v_{gs}>v_{g}, and D_{off} is forwardly biased. C_{gs} will be discharged via R_{off} and the voltage source 228. The base voltages of Q₁, Q₂, and Q₃ are thus both positive, and Q₁, Q₂, and Q₃ operate in the cut off region. When C_{gs} has been fully discharged, v_{gs}=v_{g}, which is zero or negative. Again, Q₁, Q₂, and Q₃ are still in the cut off region. In other words, the current mirror does not operate when the MOSFET is off. The voltage across Rₛ, which is vₛ, is zero.

When v_{g} is changed from logical “LOW” to logical “HIGH”, the voltage level of v_{g} will change from zero or negative to positive to turn on the SiC MOSFET. However, v_{gs} is still zero or negative because of the presence of the gate-source capacitance C_{gs}. Thus, the base-emitter voltages of Q₁ and Q₂ are thus both negative, and Q₁ and Q₂ momentarily saturate. The voltage across C₁ at this moment is still zero or negative. Thus, the base-emitter voltages of Q₃ is negative. Q₃ saturates and the duration of such saturation is controlled by the values of R₁, R₂ and C₁. A high current pulse will flow through the gate resistor R_{ON}, Q₃, and C_{gs}. The gate current i_{g} can be approximated by

$${i}_{g} = \frac{{v}_{g} - {v}_{CE , sat}}{{R}_{ON}} \qquad ( 1 )$$

where v_{CE,sat} is the collector-emitter saturation voltage of Q₁, Q₂ and Q₃.

The voltage across Rₛ, which is vₛ, is

$${v}_{s} = {v}_{{g}^{-}} {v}_{CE , sat} \qquad ( 2 )$$

As C_{gs} is charged up, the gate current and vₛ drop. Q₁ and Q₂ will gradually change from operating in the saturation mode to the cutoff mode. They will enter into the linear mode when C_{gs} discharges to a certain voltage level, at which the gate current will then be equal to the gate-source leakage current. Such duration is thus dependent on the discharging impedance across C_{gs}, such as gate-source leakage resistance, leakage current of Q₁ and Q₂, etc. In order to shorten the transition of Q₁ and Q₂ from the saturation mode to linear mode, the discharging circuit is used. When the device is turned on, Q₄ is also turned on by v_{g} through R₃. Thus, C_{gs} will discharge through R₄. Until the current mirror operates and vₛ rises. The comparator generates a “LOW” to turn off Q₄. The discharging circuit therefore significantly shortens the time of measuring the gate-source leakage current.

Assume that the base currents of Q₁ and Q₂ are much smaller than their collector currents. The collector current of Q₁, which is i_{c1}, is close to the gate current. Thus,

$${i}_{c 1} \approx {i}_{g} \qquad ( 3 )$$

Q₁ and Q₂ have similar electrical characteristics. The collector current of Q₂, which is i_{c2}, is therefore

$${i}_{c 2} \approx {i}_{c 1} \approx {i}_{g} \qquad ( 4 )$$

The current through Rₛ is the same as i_{g}. vₛ is equal to

$${v}_{s} \approx {i}_{g} {R}_{s} \qquad ( 5 )$$

Thus, the gate leakage current iₛₛ can be estimated by sensing vₛ that

$${i}_{gas} \approx \frac{1}{{R}_{s}} {v}_{s} \qquad ( 6 )$$

With the current mirror, the current through Rₛ, which is iₛ, mirrors i_{gss}.

The diodes D₁ and D₂ are used to desaturate Q₂ and Q₄ at turn on.

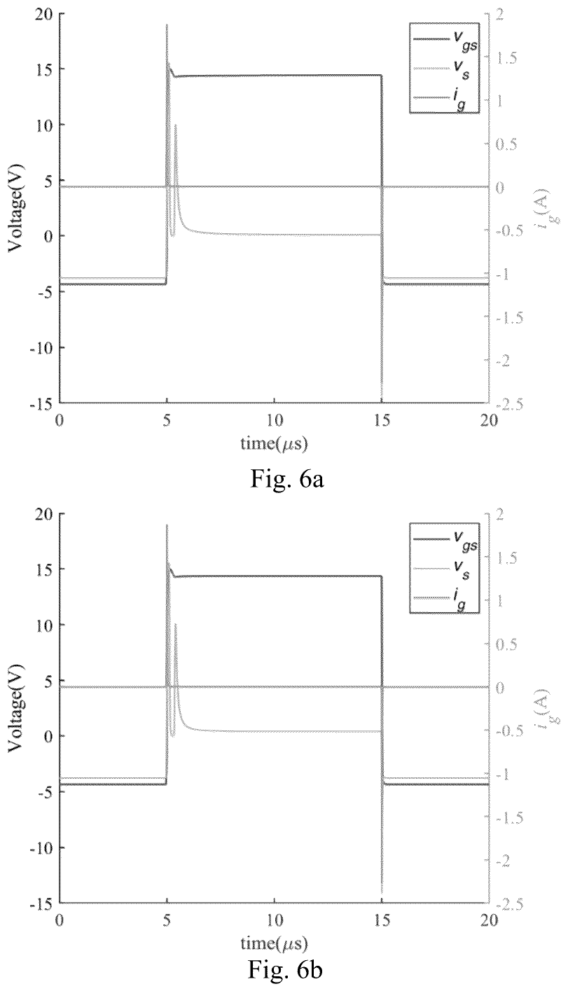

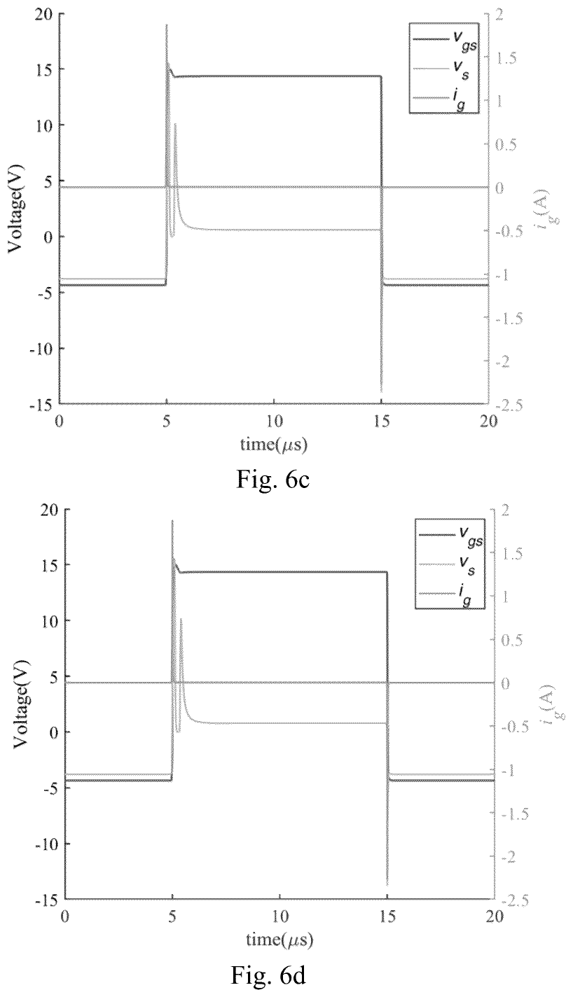

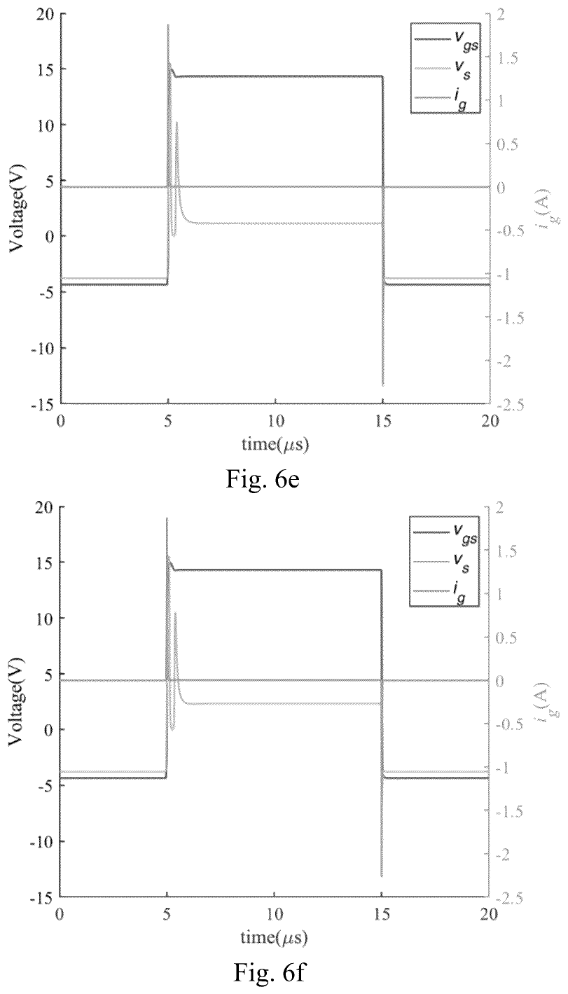

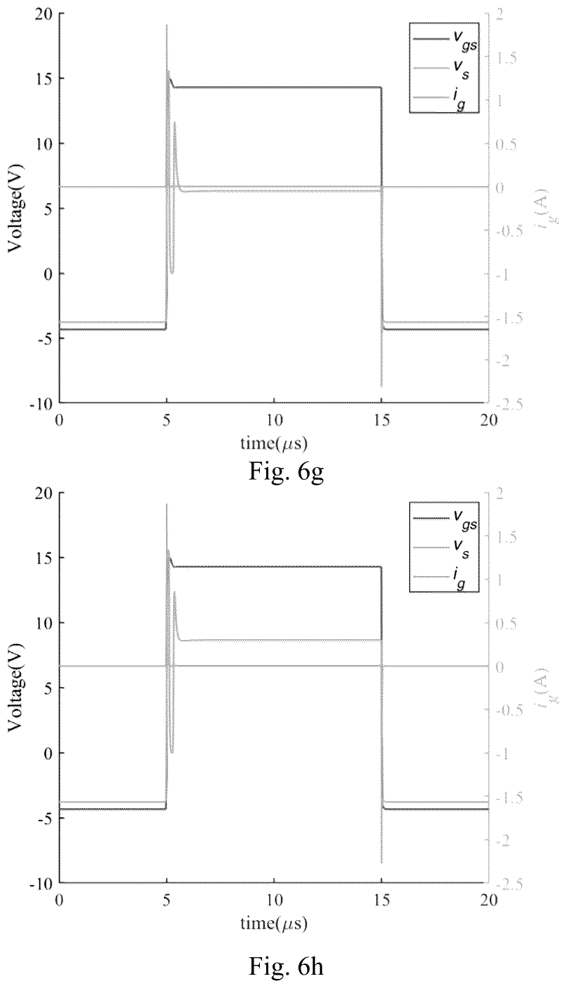

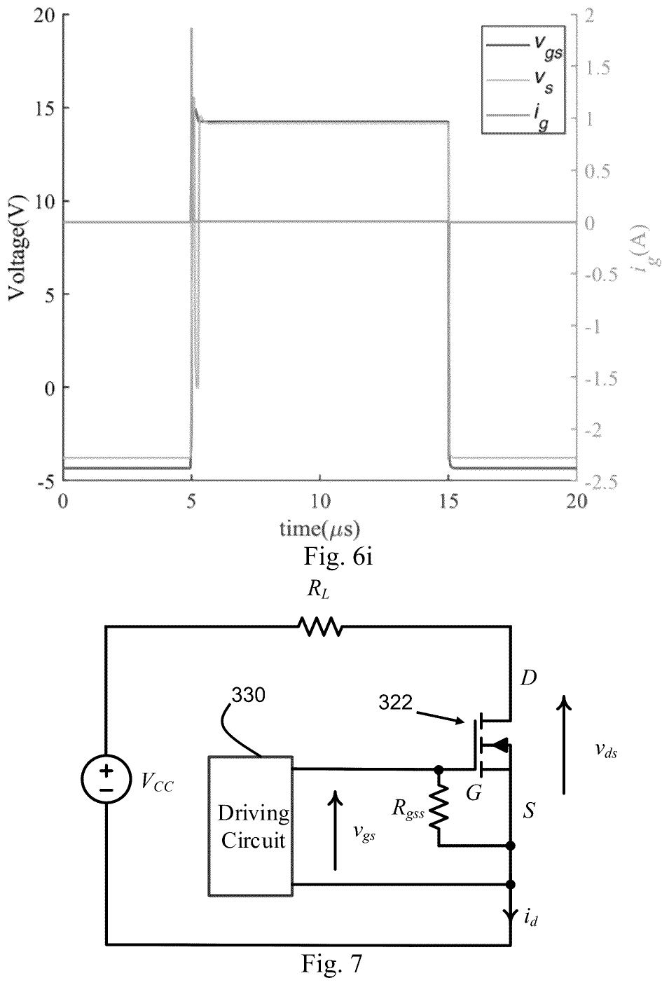

Next, the simulation results of the circuit in FIG. 5 will be discussed. In the simulation, the output of the voltage source 228 is set to switch between-5V and +15V. The component part numbers and values are given in Table I below. With Rₛ=4.7 kΩ, FIGS. 6a-6i show the waveforms of v_{gs}, vₛ and i_{g} when R_{gss} equals to ∞, 300 kΩ, 200 kΩ, 150 kΩ, 100 kΩ, 47 kΩ, 15 kΩ, 10 kΩ and 4.7 kΩ, respectively. It can be observed that vₛ is 15V in a short period for all R_{gss} because of the i_{g} due to switching transient and then keeps at steady state voltage according to the value of R_{gss}. After R_{gss} decreases, the steady state voltage of vₛ increases. When R_{gss} equals 4.7 kΩ which means i_{gss} equals to 3.2 mA, vₛ increases to 14.2V at a steady state.

TABLE I
Component Part Nos. and Values

| | Part no. / | | | Part no. / |
|---|---|---|---|---|
| Component | Value | | Component | Value |
| R₁ | 510 | Ω | C₁ | 120 pF |
| R₂ | 100 | Ω | Q₁ | 2N4126 |
| R₃ | 20 | kΩ | Q₂ | 2N4126 |
| R₄ | 2.7 | kΩ | Q₃ | 2N4126 |
| Rₛ | 4.7 | kΩ | Q₄ | 2N3391 |
| R_{ON} | 4.7 | Ω | D₁ | 1N4148 |
| R_{OFF} | 4.7 | Ω | D₂ | 1N4148 |
| | | | D_{OFF} | 1N4148 |

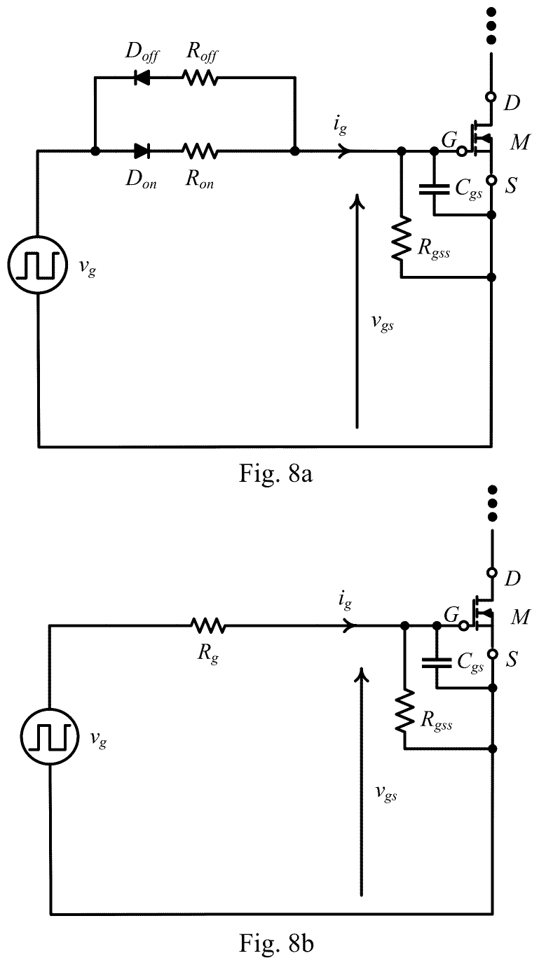

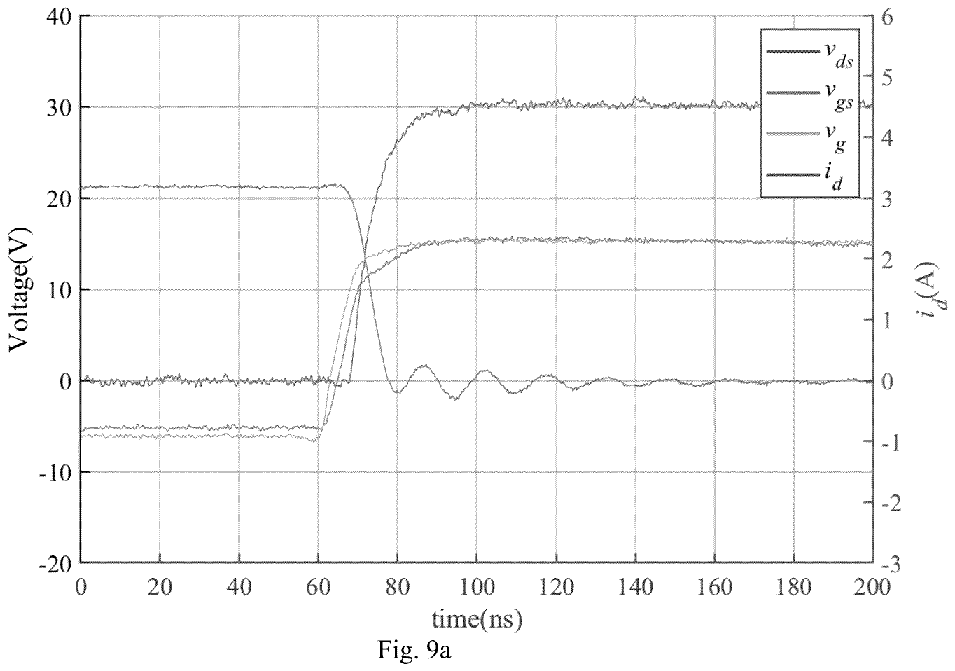

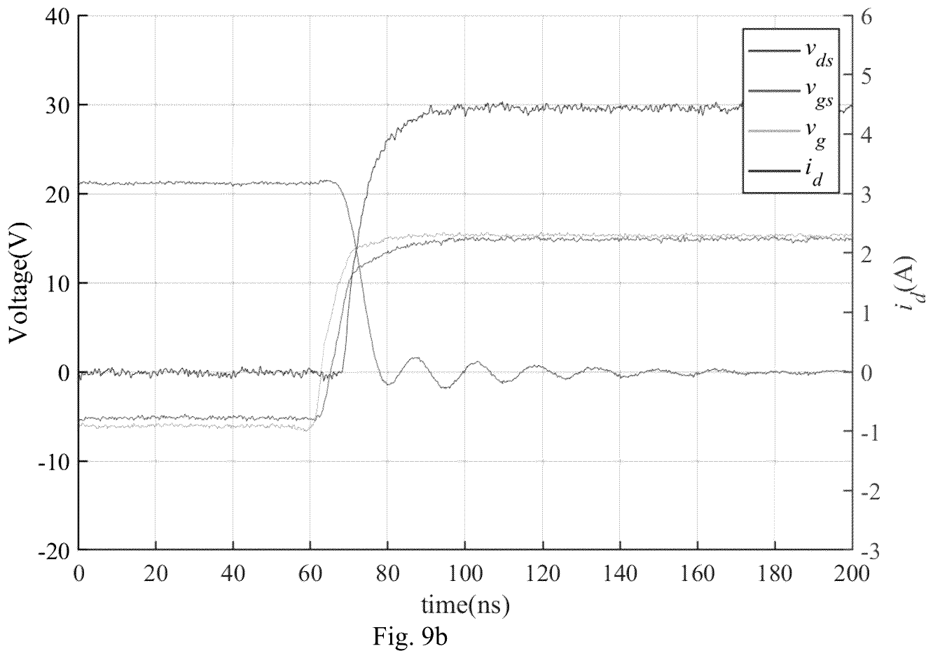

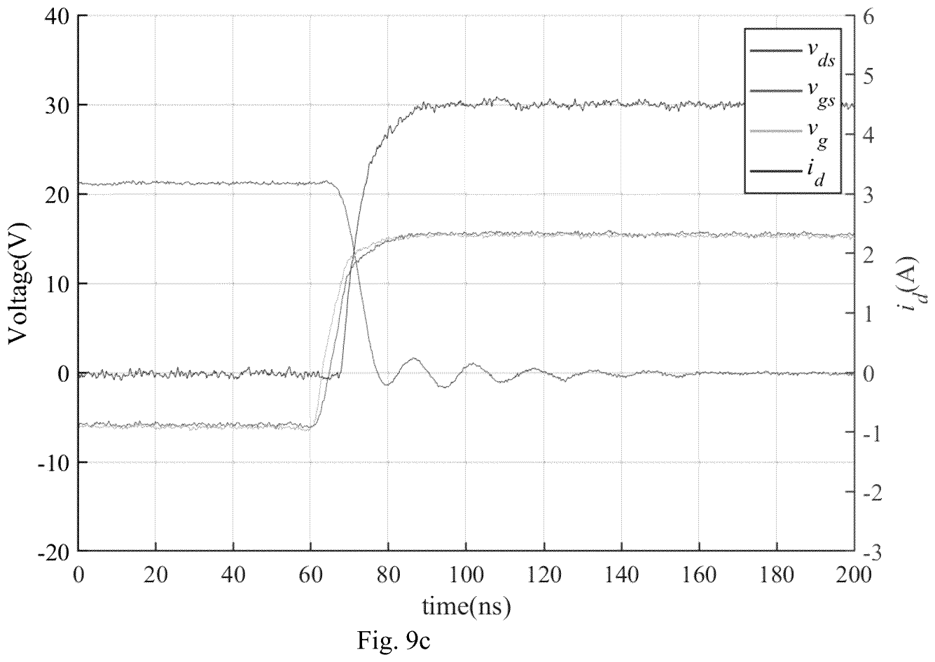

Besides the simulation, the apparatus for measuring the gate leakage circuit in FIG. 5 has also been validated experimentally. FIG. 7 shows the test circuit used for the experiment, which includes a SiC MOSFET 322, a driving circuit 330 in FIG. 7, and a load resistor R_{L}. The supply voltage to the SiC MOSFET 322 is V_{CC}. The switching frequency is 50 kHz. A resistor R_{gss}, which is connected across the gate and source of the SiC MOSFET, is used to adjust the steady-state gate current to emulate the gate leakage current of the SiC MOSFET. The emulated gate leakage current will be small when R_{gss} is large. Conversely, it will be large when R_{gss} is small. Three different driving circuits have been tested, which are respectively the circuit shown in FIG. 5, the circuit shown in FIG. 8a (which does not have a current mirror), and the circuit shown in FIG. 8b (which does not have a current mirror or a polarized resistive network, and includes simply a gate resistor). These three driving circuits individually represent the driving circuit 330 when they are implemented in the test circuit. The component part numbers and values of the three driving circuits are given in Table II. The measured waveforms of the drain-source voltage, v_{ds}, gate-source voltage, v_{gs}, output voltage of the gate driver, v, and drain current. i_{d}, upon turning on the SiC MOSFET for the three circuits are given in FIGS. 9a-9c respectively. No R_{gss} is connected to the driving circuit. The drain-source voltage before turning on is 20V. The transient and steady-state characteristics are given in Table II. The nomenclature of the symbols is given as follows:
V_{ds,ON}: Steady-state on-state value of v_{ds}
t_{ds,f}: Fall time of v_{ds} (From 90% to 10% of the steady-state value)
V_{g,ON}: Steady-state on-state value of v_{g}
t_{g,r}: Rise time of v_{g} (From 10% to 90% of the steady-state value)
V_{gs,ON}: Steady-state on-state value of v_{gs}
t_{gs,r}: Rise time of v_{gs} (From 10% to 90% of the steady-state value)
I_{d,ON}: Steady-state on-state value of i_{d}
t_{d,r}: Rise time of i_{d} (From 10% to 90% of the steady-state value)

TABLE II
Component Part Nos. and Values

| | | | |
|---|---|---|---|
| | Part no. / | | Part no. / |
| Component | Value | Component | Value |

For the circuit shown in FIG. 5:

| | | | | | |
|---|---|---|---|---|---|
| R₁ | 510 | Ω | C₁ | 120 | pF |

| | | | | |
|---|---|---|---|---|
| R₂ | 100 | Ω | Q₁ | 2SA1978 |
| R₃ | 20 | kΩ | Q₂ | 2SA1978 |
| R₄ | 2.7 | kΩ | Q₃ | 2SA1978 |
| Rₛ | 4.7 | kQ | Q₄ | MMBTH10 |
| Rₒₙ | 4.7 | Ω | D₁ | DB2731400L |
| R_{off} | 4.7 | Ω | D₂ | DB2731400L |
| | | | D_{off} | 1N4148 |

For the circuit shown in FIG. 8a:

| | | | | | |
|---|---|---|---|---|---|
| Rₒₙ | 4.7 | Ω | R_{off} | 4.7 | Ω |

| | | | |
|---|---|---|---|
| D_{off} | 1N4148 | D_{off} | 1N4148 |

For the circuit shown in FIG. 8b:

| | | |
|---|---|---|
| R_{g} | 4.7 | Ω |

TABLE III
Transient and Steady-State Characteristics

| | | | |
|---|---|---|---|
| | Circuit shown | Circuit shown | Circuit shown |
| Parameter | in FIG. 5 | in FIG. 8a | in FIG. 8b |

| | | | | | | |
|---|---|---|---|---|---|---|
| V_{ds, ON} | 0 | V | 0 | V | 0 | V |
| t_{ds, f} | 7 | ns | 7 | ns | 7 | ns |
| V_{g, ON} | 15 | V | 15 | V | 15 | V |
| t_{g, r} | 9.2 | ns | 8.4 | ns | 8.8 | ns |
| V_{gs, ON} | 14.3 | V | 14.5 | V | 15 | V |
| t_{gs, r} | 13.2 | ns | 12.6 | ns | 10.6 | ns |
| I_{d, ON} | 4.6 | A | 4.6 | A | 4.6 | A |
| t_{d, r} | 13.8 | ns | 13.6 | ns | 13.6 | ns |

Based on the measured parameters, it can be observed that the driving circuit/current measurement circuit in FIG. 5 slightly lengthen the rise time of v_{g} and v_{gs}, but the turn-on time of v_{ds} and i_{d} is nearly the same. The steady-state gate-source voltage slightly drops, because of the small voltage drop across the current mirror.

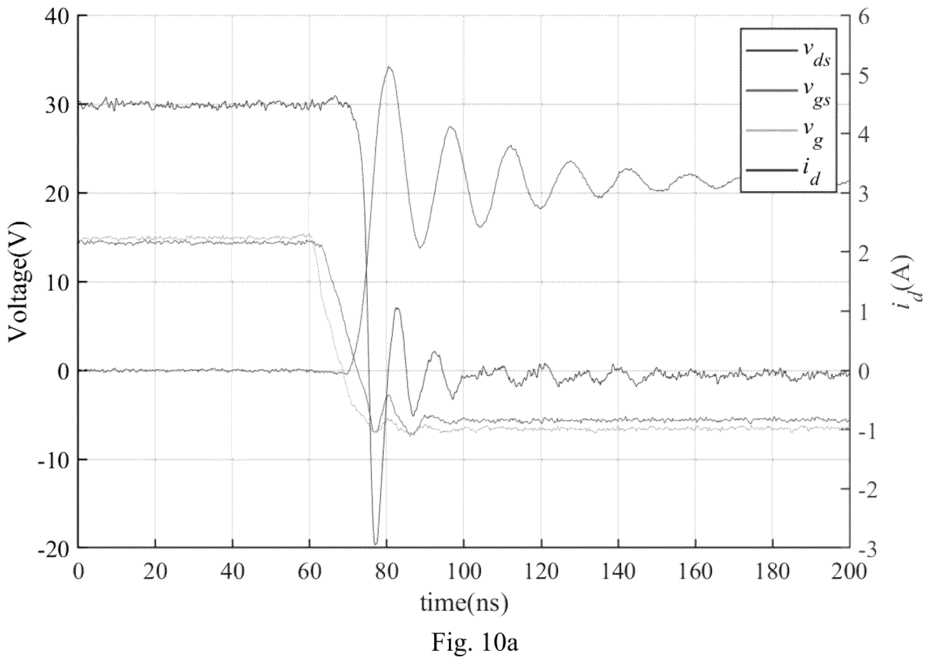

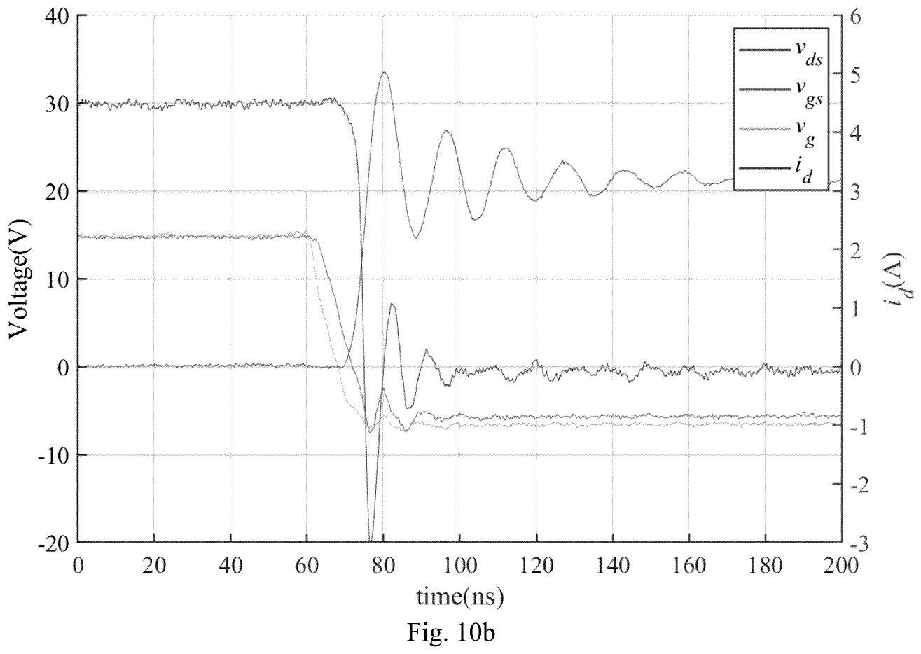

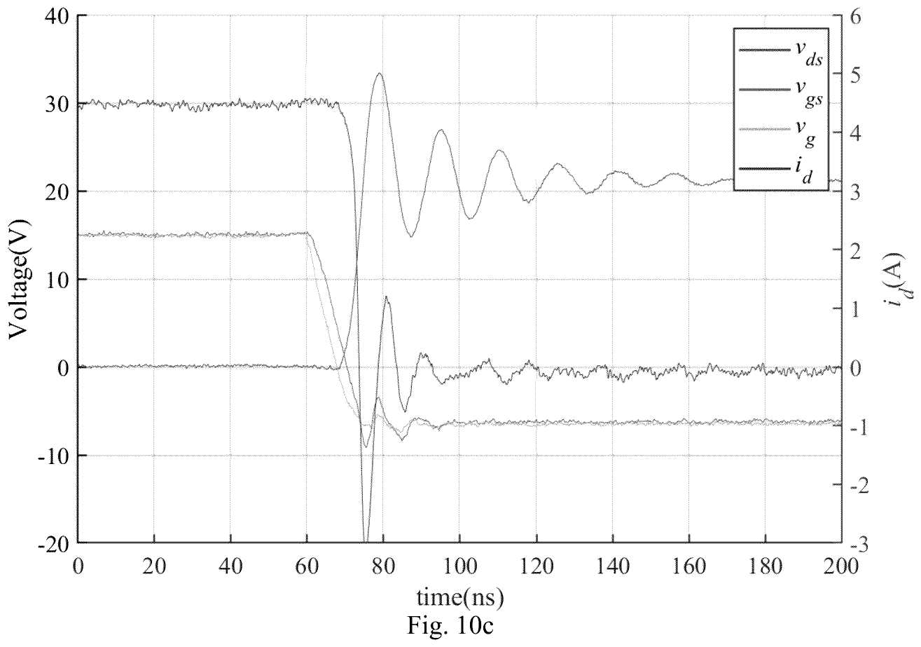

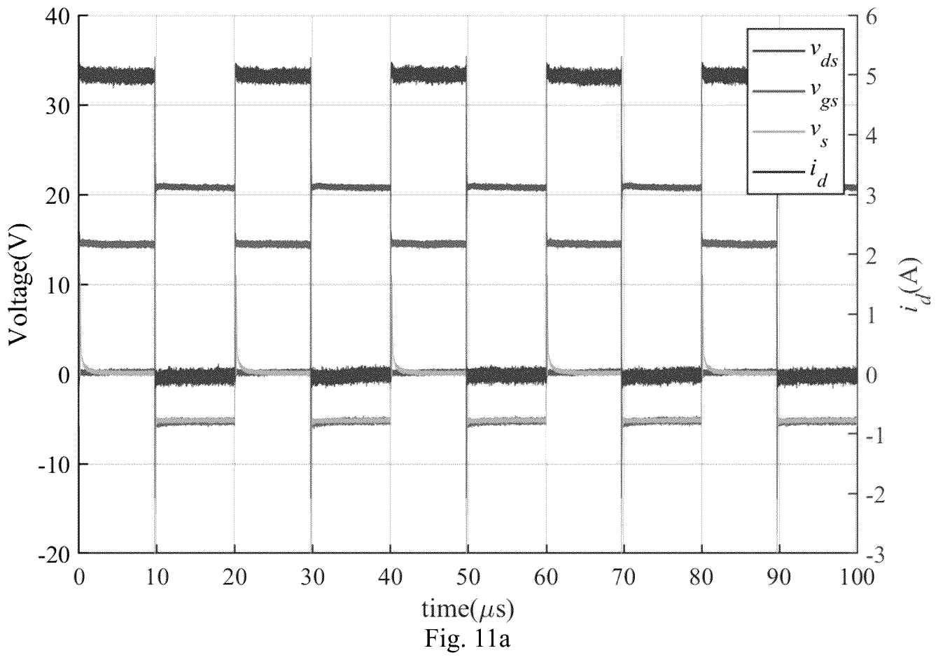

The measured waveforms of the drain-source voltage, v_{ds}, gate-source voltage, v_{gs}, output voltage of the gate driver, v_{g}, and drain current. i_{d}, upon turning off the SiC MOSFET for the three circuits are given in FIGS. 10a-10c respectively. The drain current before turning off is 4.6 A. The transient and steady-state characteristics are given in Table IV. The nomenclature of the symbols is given as follows:
V_{ds,OFF}: Steady-state off-state value of v_{ds}
t_{ds,r}: Rise time of v_{ds} (10% to 90% of the steady-state value)
v_{g,OFF}: Steady-state off-state value of v_{g}
t_{g,f}: Fall time of v_{g} (90% to 10% of the steady-state value)
V_{gs,OFF}: Steady-state off-state value of v_{gs}
t_{gs,f}: Fall time of v_{gs} (90% to 10% of the steady-state value)
I_{d,OFF}: Steady-state off-state value of i_{d}
t_{d,f}: Fall time of i_{d} (90% to 10% of the steady-state value)

TABLE IV
Transient and Steady-State Characteristics

| | | | |
|---|---|---|---|
| | Circuit shown | Circuit shown | Circuit shown |
| Parameter | in FIG. 5 | in FIG. 8a | in FIG. 8b |

| | | | | | | |
|---|---|---|---|---|---|---|
| V_{ds} | 20.9 | V | 20.9 | V | 20.9 | V |
| t_{ds, r} | 4.2 | ns | 4.2 | ns | 4.2 | ns |

| | | | |
|---|---|---|---|
| V_{g} | −6 | −6 | −6 |

| | | | | | | |
|---|---|---|---|---|---|---|
| t_{g, f} | 9.4 | ns | 9 | ns | 9.6 | ns |

| | | | |
|---|---|---|---|
| V_{gs} | −5.6 | −5.6 | −6 |

| | | | | | | |
|---|---|---|---|---|---|---|
| t_{gs, f} | 10.8 | ns | 10.8 | ns | 11 | ns |
| I_{d, OFF} | 0 | A | 0 | A | 0 | A |
| t_{d, f} | 3.2 | ns | 3.2 | ns | 3.4 | ns |

Since the turn-off process only involves R_{off} and D_{off}, based on the measured parameters, it can be observed that the fall time of v_{g} and v_{gs} and the turn-off time of v_{ds} and i_{d} of the circuit of FIG. 5 is nearly the same. The steady-state gate-source voltage slightly drops because of the small voltage drop across the diode.

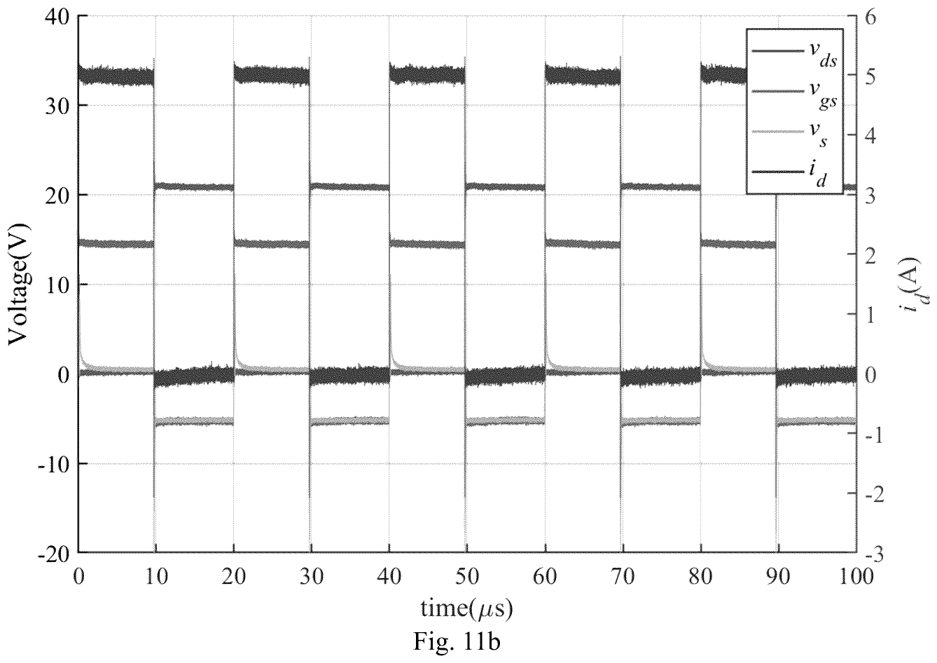

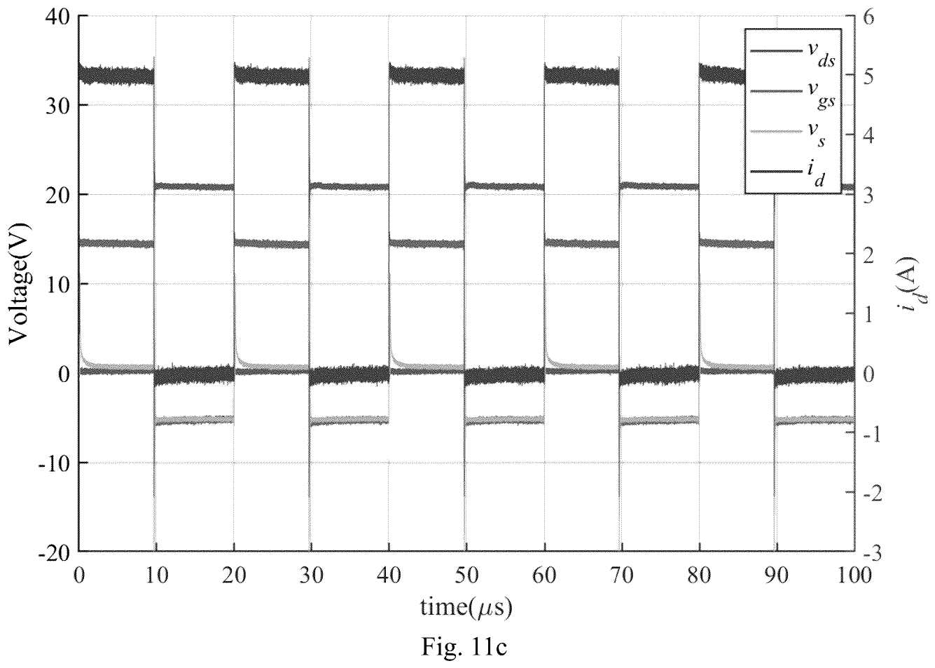

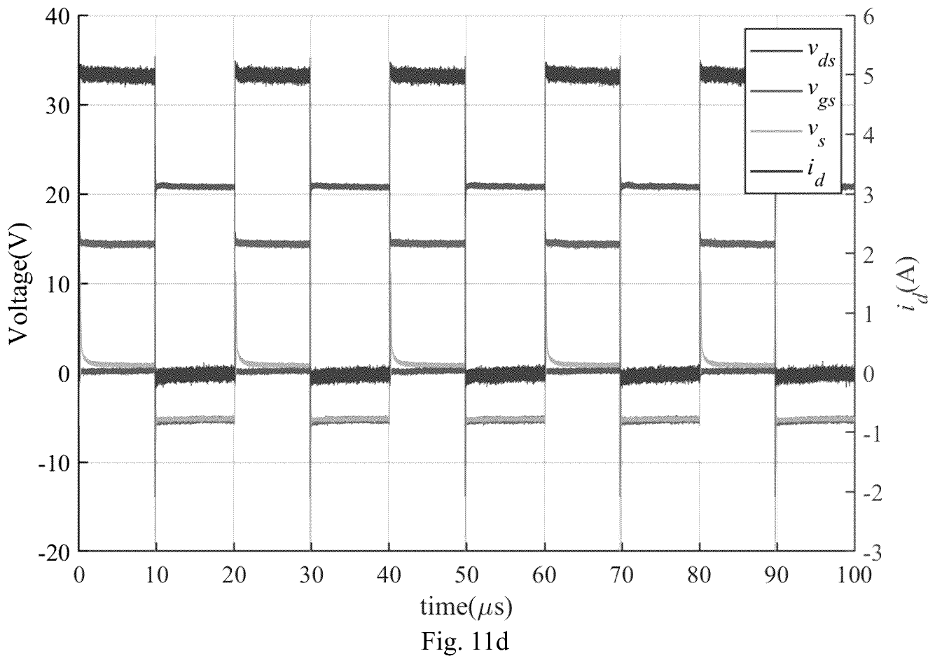

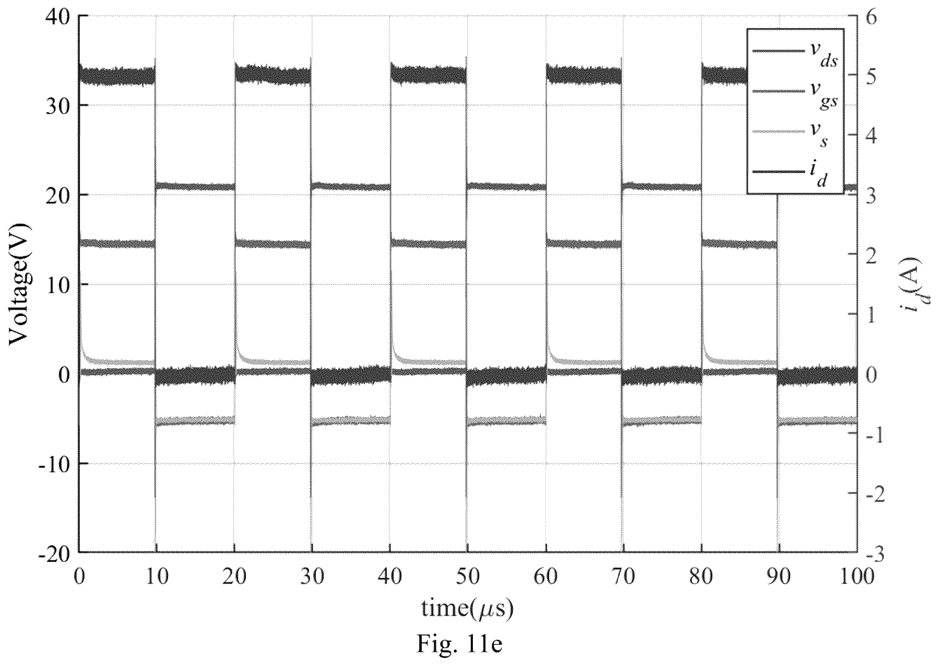

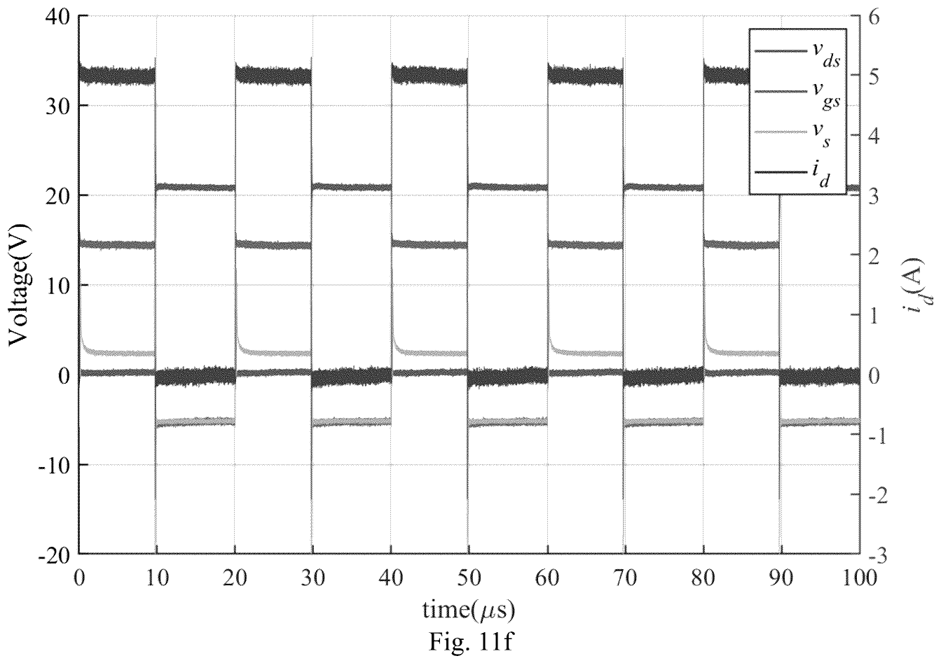

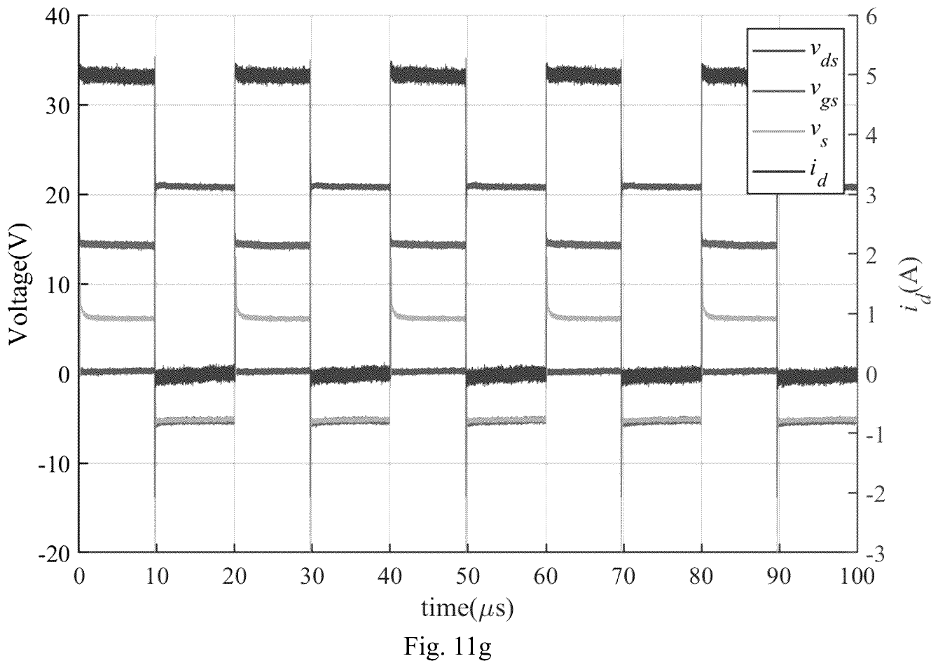

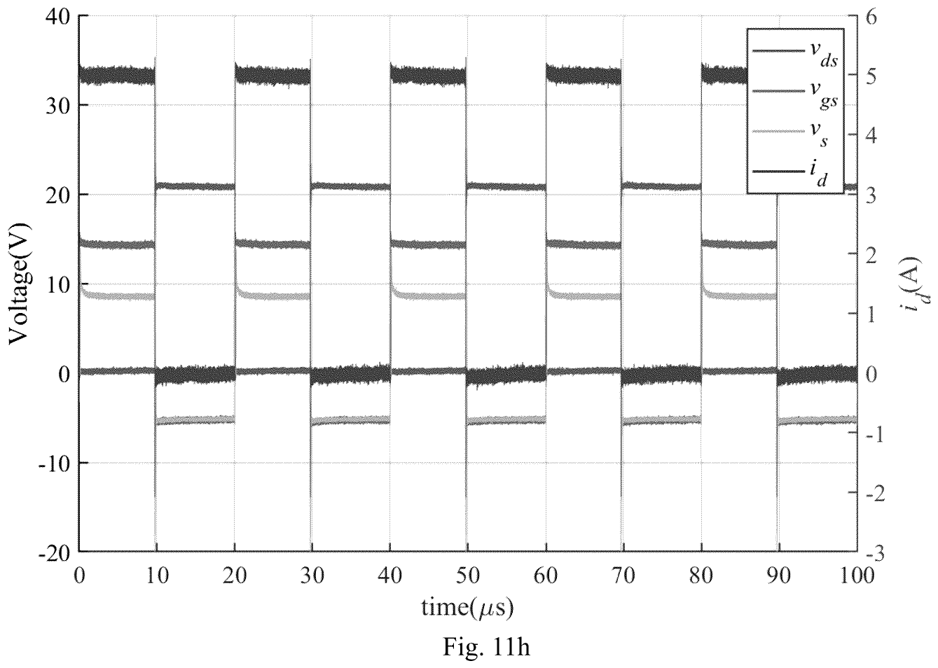

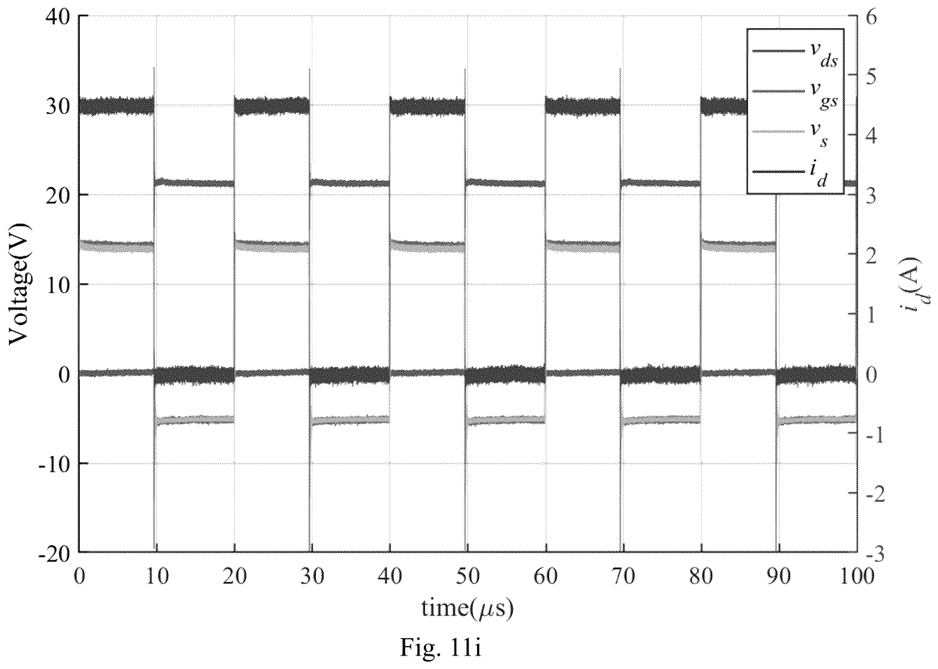

The waveforms of vₛ under different values of R_{gss} are observed. FIGS. 11a-11i show the waveforms of vₛ when R_{gss} equals to 0, 300 kΩ, 200 kΩ, 150 kΩ, 100 kΩ, 47 kΩ, 15 kΩ, 10 kΩ and 4.7 kΩ, respectively. The switching frequency is 50 kHz and the duty cycle D of the SiC MOSFET is 0.5. vₛ takes approximately 500 ns before reaching the steady state. The steady-state value of vₛ against different R_{gss} and gate leakage current I_{gss} are tabulated in Table V.

TABLE V
Steady-state value of vₛ against different R_{gss} and duty cycle D

vₛ

| R_{gss} | I_{gss} | | D = 0.2 | D = 0.5 | D = 0.8 |
|---|---|---|---|---|---|
| ∞ | 0 | mA | 0.6 | 0.6 | 0.6 |

| | | | | | | |
|---|---|---|---|---|---|---|
| 300 | kΩ | 0.05 | mA | 0.8 | 0.9 | 0.9 |
| 200 | kΩ | 0.075 | mA | 1 | 1.1 | 1.1 |
| 150 | kΩ | 0.1 | mA | 1.2 | 1.3 | 1.3 |
| 100 | kΩ | 0.15 | mA | 1.5 | 1.7 | 1.6 |
| 47 | kΩ | 0.32 | mA | 2.6 | 2.7 | 2.7 |
| 15 | kΩ | 1.0 | mA | 6.4 | 6.4 | 6.4 |
| 10 | kΩ | 1.5 | mA | 8.7 | 8.8 | 8.8 |
| 4.7 | kΩ | 3.2 | mA | 14.1 | 14.1 | 14.1 |

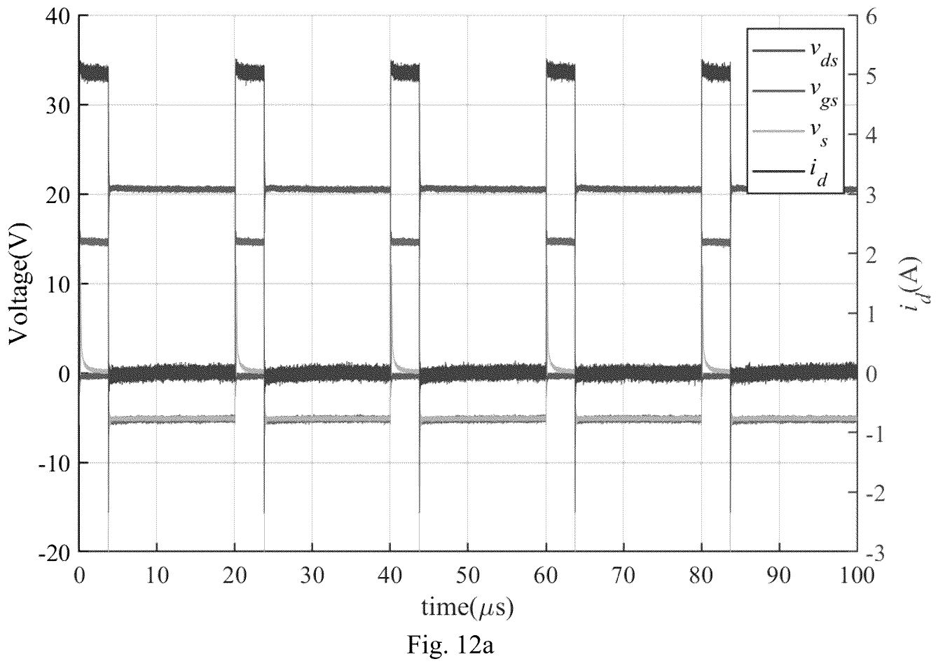

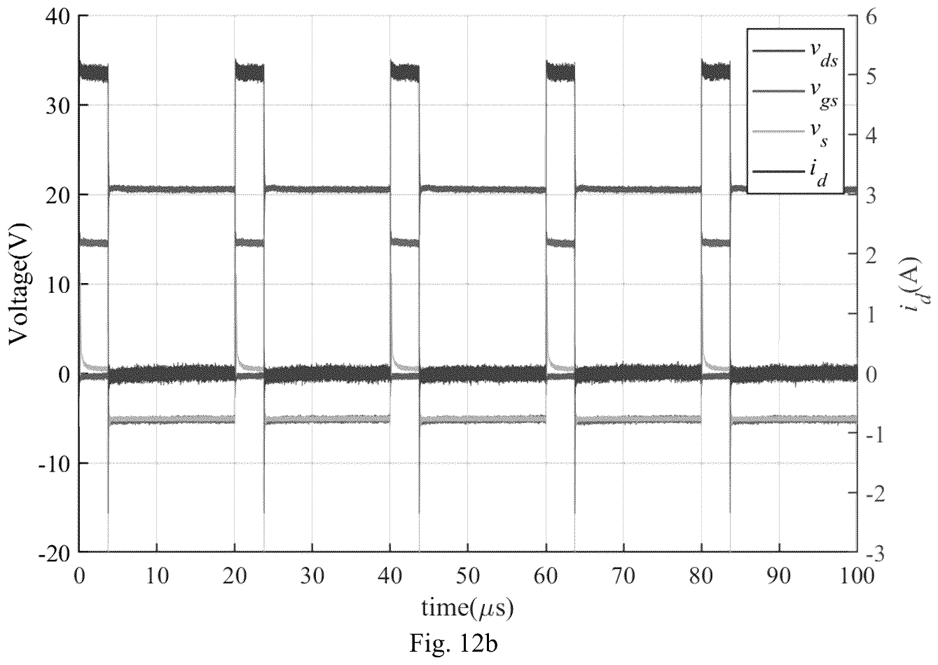

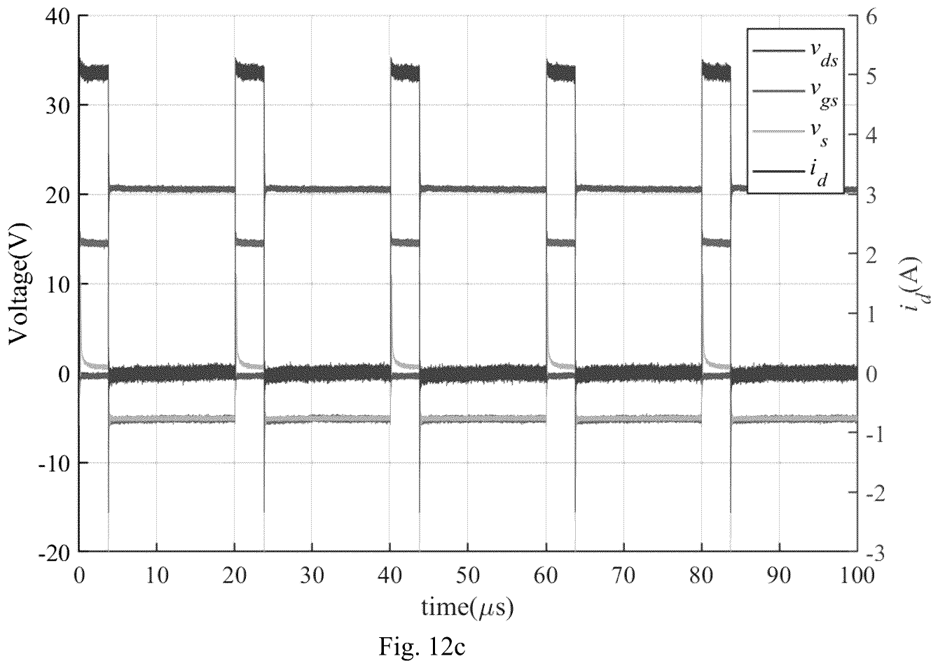

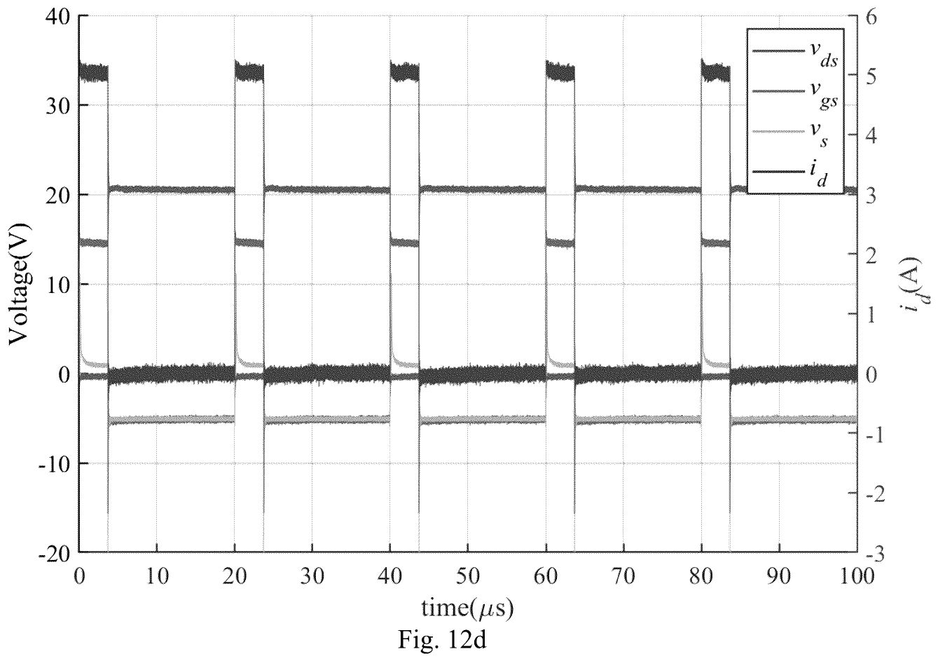

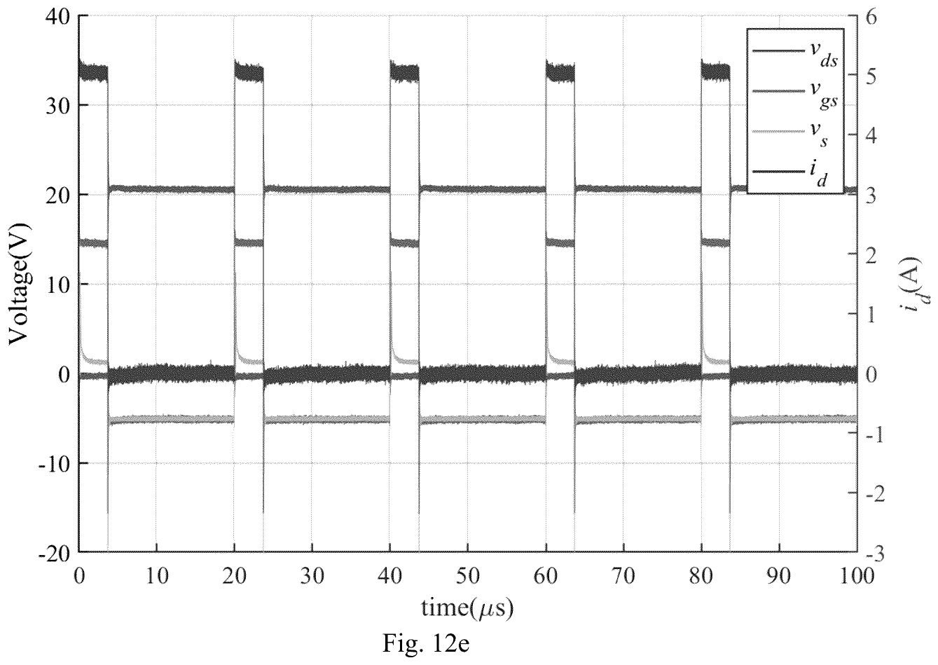

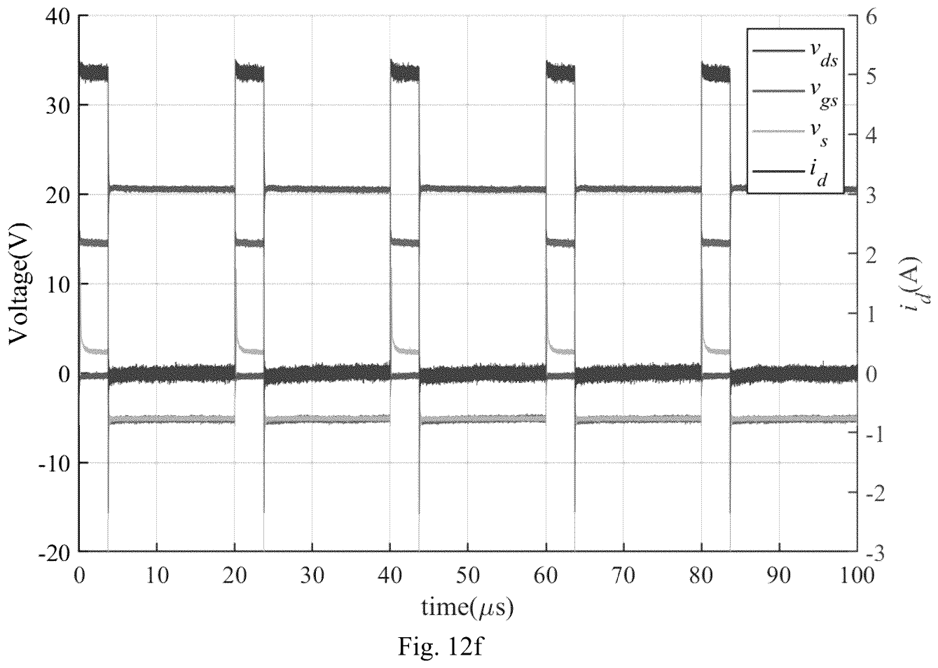

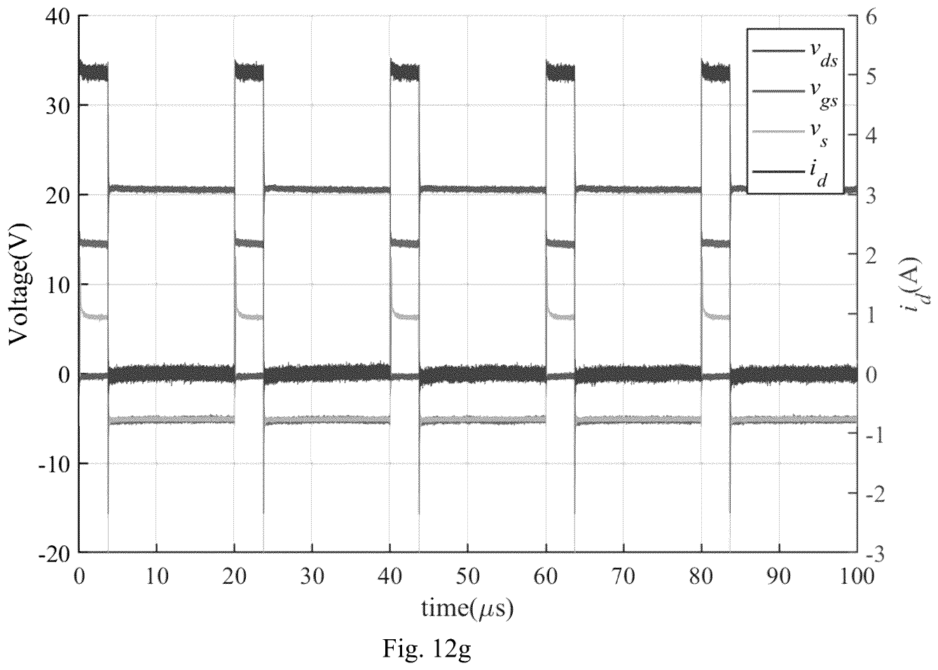

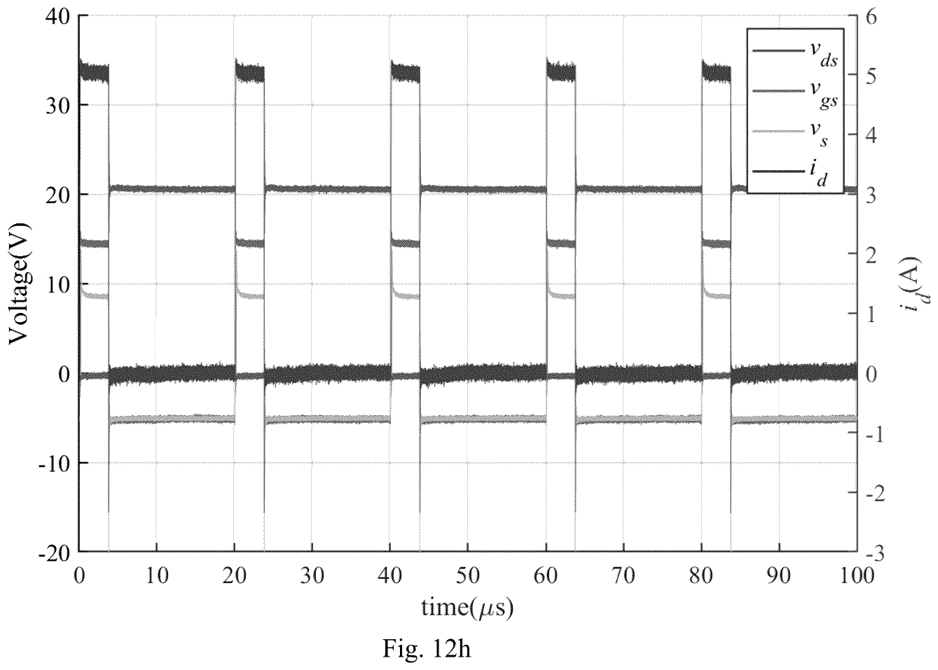

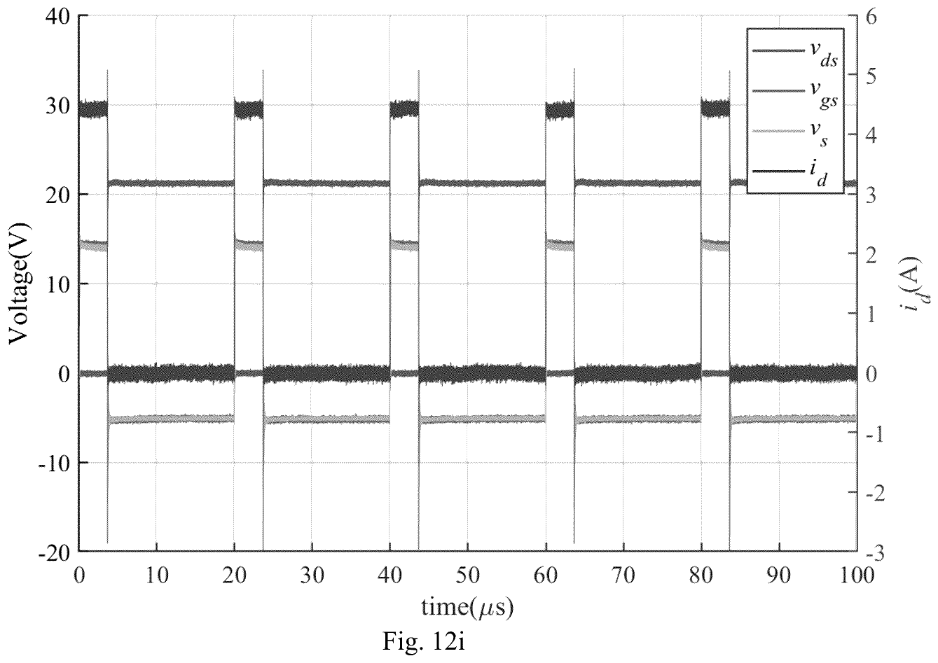

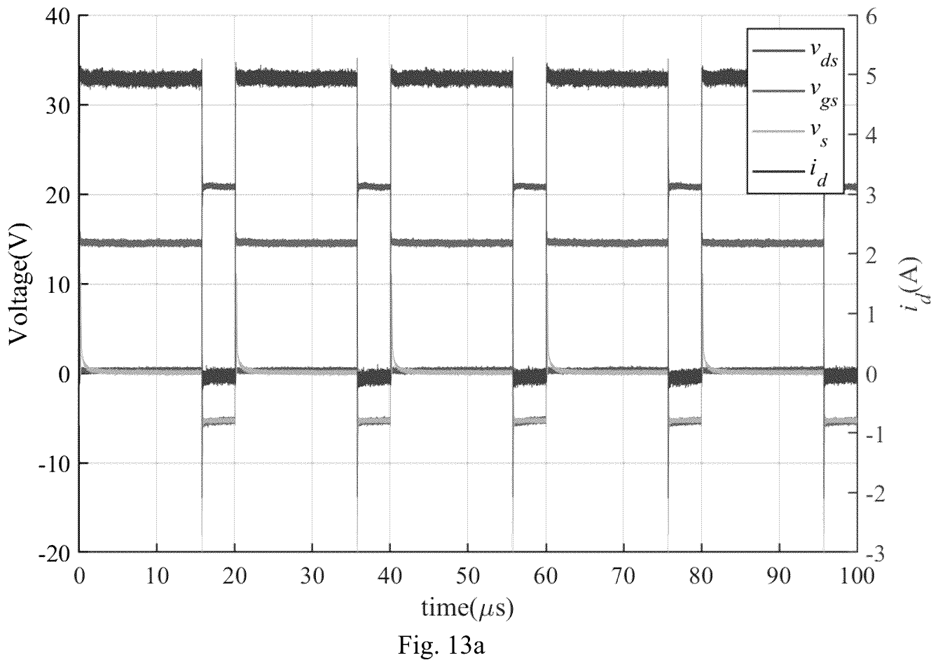

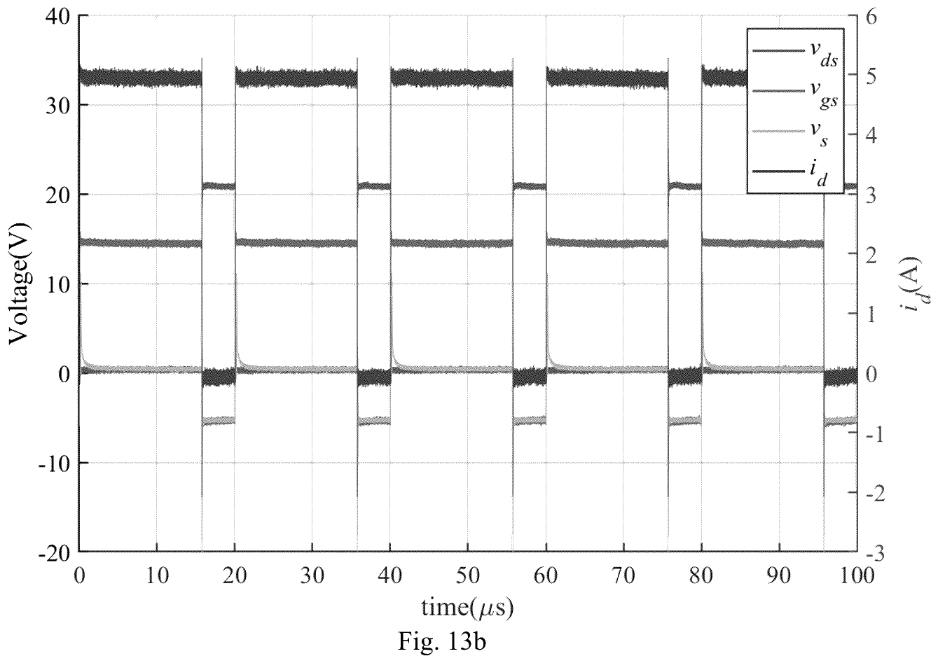

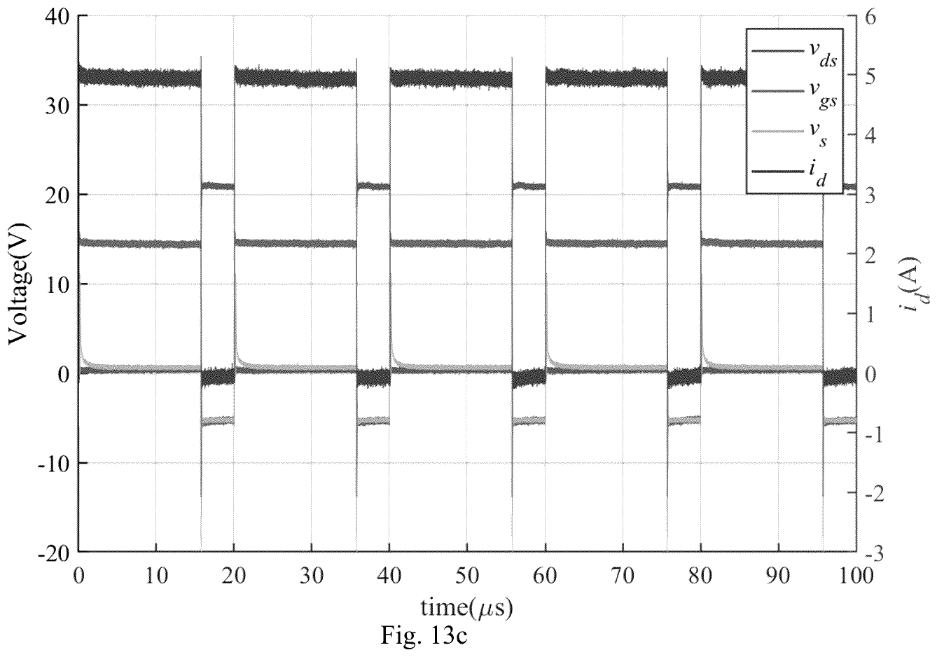

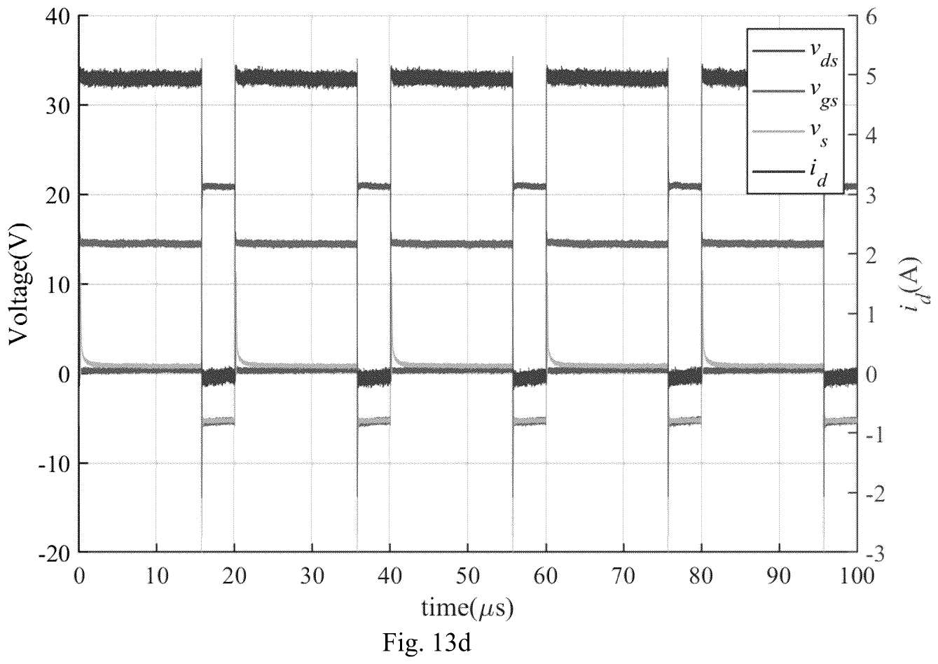

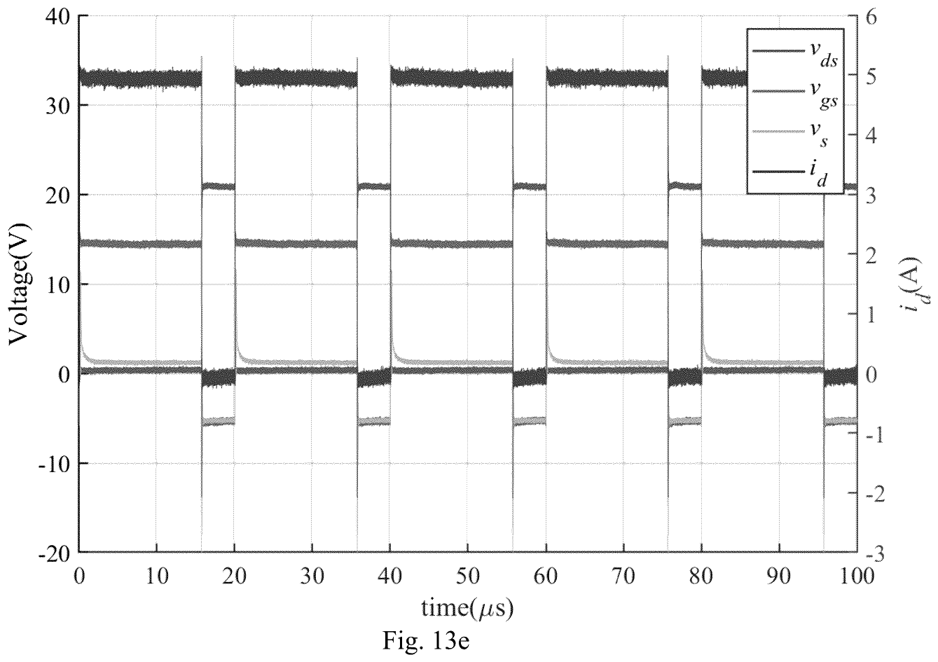

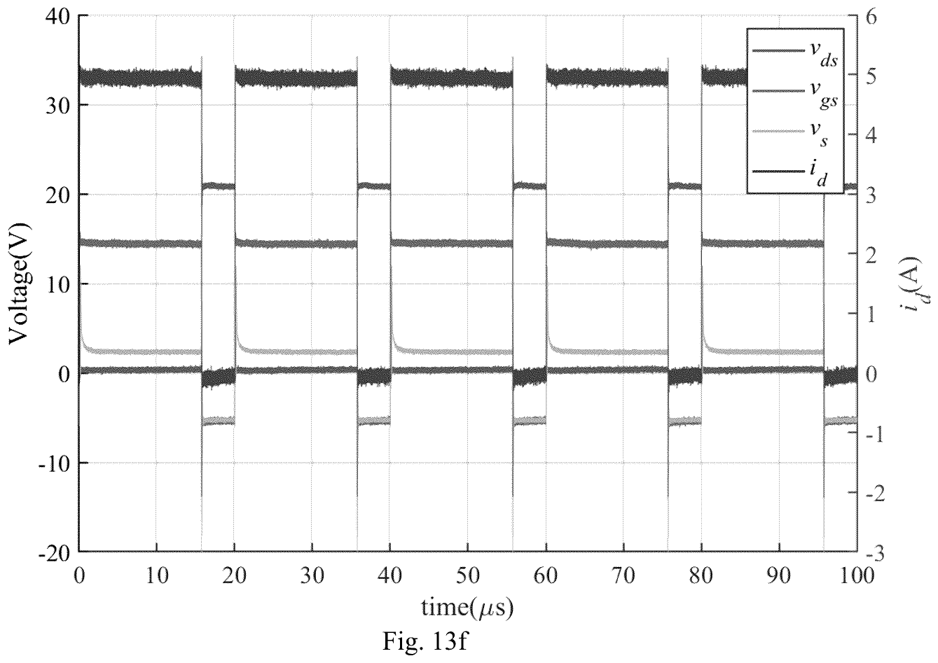

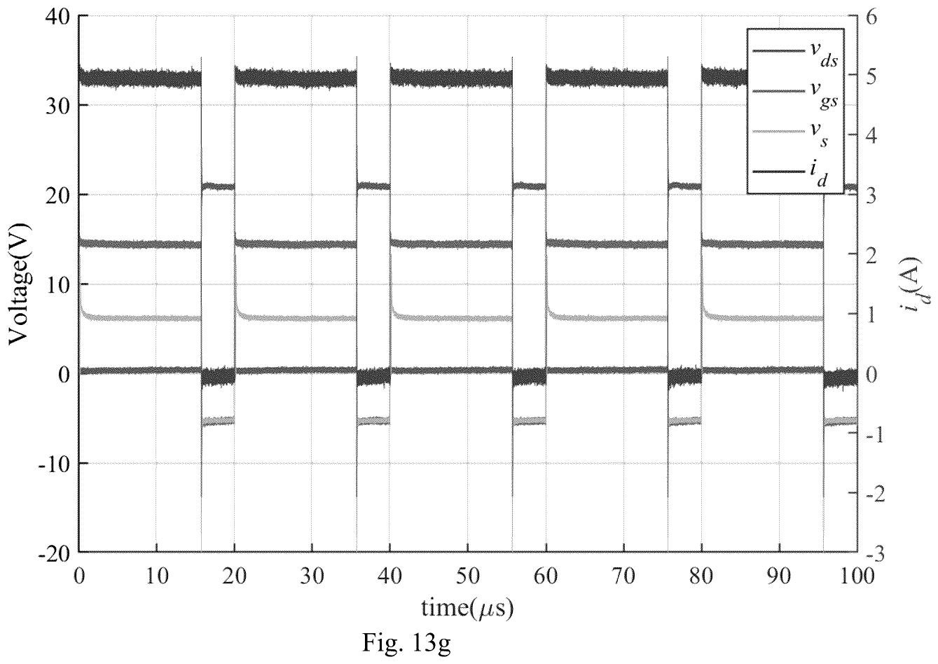

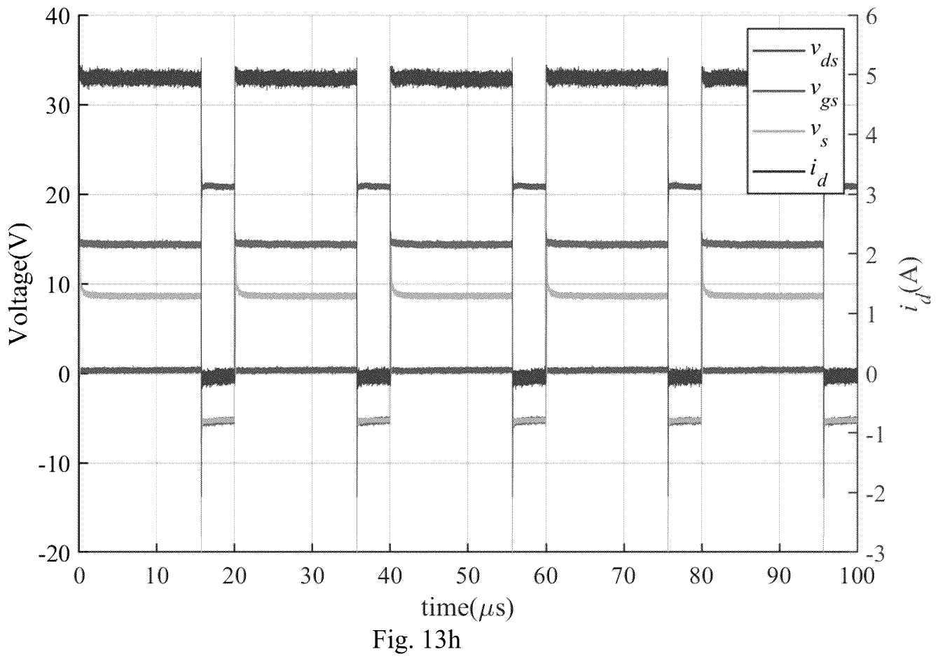

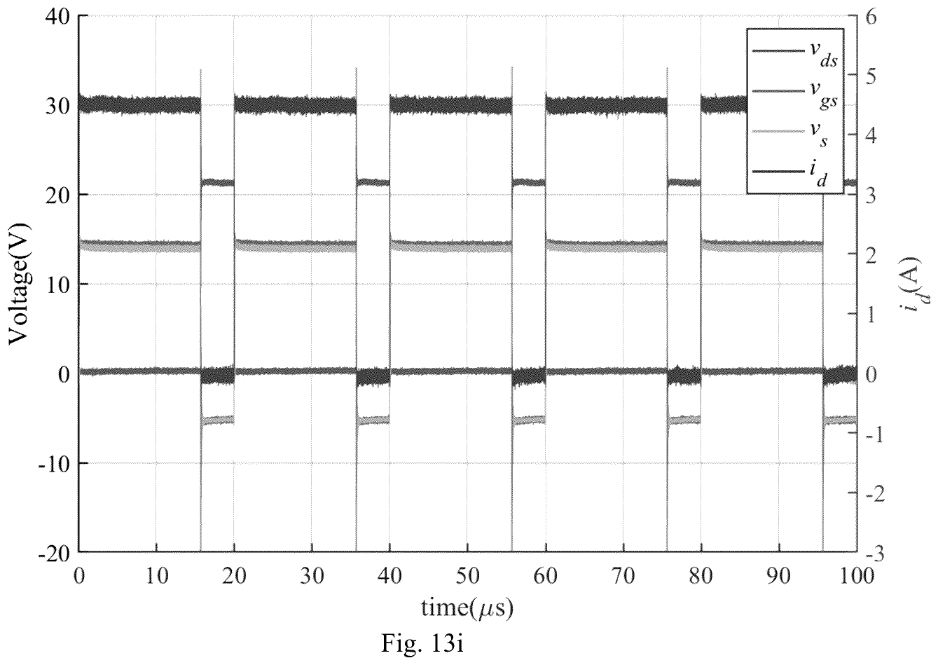

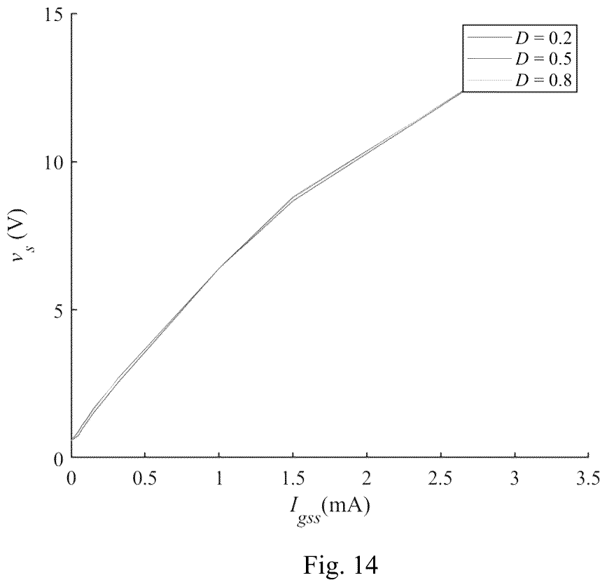

With D=0.2 and D=0.8, the steady-state values of vₛ are given in Table V. The waveforms under these two duty cycle conditions are shown in FIGS. 12a-12i and FIGS. 13a-13i respectively. The relationships between vₛ and I_{gss} are shown in FIG. 14. It can be observed that vₛ is nearly independent of the duty cycle and varies with R_{gss} and thus I_{gss}. It can be used to detect the gate leakage current. It can be sensed by a microcontroller to detect the gate leakage condition of the SiC MOSFET.

In summary, one can see that the circuit shown in FIG. 5 provides a gate driving circuit including a current mirror to perform switching operation and monitoring the gate source leakage current simultaneously. The basic structure is a current mirror that mirrors the gate leakage current i_{g} to a sensing resistor Rₛ. It includes the basic structure for measuring i_{g}, a bypass circuit for improving the switching speed, and a discharge circuit to enhance the dynamic response. The circuit has been tested on a 100 W switching circuit. The experimental results show that the switching speed of the MOSFET when using the proposed circuit is nearly the same as using a polarized network or a single R_{g}. Then, by inserting R_{gss}, the results show that the proposed circuit can perform sensing of the current through R_{gss}. Moreover, with the duty cycle of the MOSFET varying from 20% to 80%, the experimental results show that the sensing operation of the circuit of FIG. 5 is independent of the duty cycle of the gate signal.

The exemplary embodiments of the present invention are thus fully described. Although the description referred to particular embodiments, it will be clear to one skilled in the art that the present invention may be practiced with variation of these specific details. Hence this invention should not be construed as limited to the embodiments set forth herein.

While the invention has been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

For example, although specific current mirror and discharging circuits are illustrated in FIGS. 4-5 with accompany descriptions, these are only those used in some embodiments of the invention. In a general sense, the current mirror structure can vary as long as its purpose remains consistent: to measure the gate current and mirror it to a sensing resistor. Similarly, the bypass switch can take on different structures as long as it effectively bypasses the current mirror during the turn-on process to drive the MOSFET. The specific design and structure of these modules/components can be adapted to suit the requirements and constraints of the system while still fulfilling their intended functions.

What is claimed is:

1. An apparatus for measuring a gate leakage current of a MOSFET, comprising:
a) a current mirror adapted to be connected to a gate of a MOSFET; an input current path of the current mirror adapted to receive a gate leakage current of the MOSFET;
b) a gate driver adapted to generate a driving signal for the MOSFET; and
c) a sensing resistor connected to the current mirror; the sensing resistor being located on an output current path of the current mirror.

2. The apparatus of claim 1, further comprises a turn-on resistor and a turn-off resistor, both of which are adapted to be connected to the gate of the MOSFET.

3. The apparatus of claim 2, wherein the turn-on resistor is located on the input current path of the current mirror; the turn-off resistor having one end adapted to be connected to the MOSFET, and another end connected to the gate driver.

4. The apparatus of claim 1, wherein the current mirror comprises a first transistor and a second transistor having their base connected together; a collector of the first transistor adapted to be connected to the gate of the MOSFET; a collector of the second transistor connected to the sensing resistor.

5. The apparatus of claim 4, wherein the collector of the first transistor is connected directly to the base of thereof; the apparatus further comprising a diode that is connected between the collector and the base of the second transistor.

6. The apparatus of claim 4, wherein an emitter of the first transistor and an emitter of the second transistor are connected directly to the gate driver.

7. The apparatus of claim 1, further comprises a bypass switch connected in parallel to the current mirror; the bypass switch adapted to bypass the current mirror during a turn-on process of the MOSFET.

8. The apparatus of claim 1, wherein the bypass switch comprises a third transistor; the third transistor located on a current path from the gate driver to the MOSFET.

9. The apparatus of claim 8, wherein an emitter of the third transistor is connected to the gate driver; a collector of the third transistor adapted to connect to the MOSFET; a base of the third transistor connected to the gate driver through a RC circuit.

10. The apparatus of claim 4, further comprises a discharging circuit connected to the current mirror; the discharging circuit adapted to shorten a timer period required for the first transistor and the second transistor to transit from a saturation mode to a linear mode.

11. The apparatus of claim 10, wherein the discharging circuit comprises a comparator which has a first input connected to a reference voltage and a second input connected to the sensing resistor, a fourth transistor having a base connected an output of the comparator; a fourth resistor adapted to be connected between a collector of the fourth transistor and the gate of the MOSFET; and a third resistor connected between the base of the fourth transistor and a collector of the first transistor.

12. The apparatus of claim 11, further comprises a diode connected between the base and the collector of the fourth transistor.

13. The apparatus of claim 1, wherein one end of the sensing resistor is connected to the current mirror, and another end of the of the sensing resistor is connected to a source of the MOSFET.
